(19) United States
(12) Patent Application Publication
(10) Pub. No.: US 2026/0068139 A1
(43) Pub. Date: Mar. 5, 2026

(54) SEMICONDUCTOR MEMORY DEVICE

(71) Applicant: Samsung Electronics Co., Ltd., Suwon-si (KR)

(72) Inventors: Sung Nam LYU, Suwon-si (KR); Sukhoon KIM, Suwon-si (KR); Hyojung NOH, Suwon-si (KR); Dosun LEE, Suwon-si (KR); Jaehun HAN, Suwon-si (KR)

(21) Appl. No.: 19/234,609

(22) Filed: Jun. 11, 2025

(30) Foreign Application Priority Data
Aug. 28, 2024 (KR) 10-2024-0116220

(51) Int. Cl. H10B 12/00; H10D 1/68; H10D 30/01; H10D 62/10; H10D 64/27

(52) U.S. Cl. CPC H10B 12/482; H10D 1/714; H10D 30/023; H10D 62/102; H10D 64/518

(57) ABSTRACT

A semiconductor memory device includes: a back gate electrode, which includes a first conductive pattern, on a substrate; a first gate electrode, which includes a second conductive pattern, on the back gate electrode; and a first semiconductor pattern between the back gate electrode and the first gate electrode, wherein the first conductive pattern and the second conductive pattern include respective materials and/or have respective physical properties different from each other.

### CROSS-REFERENCE TO RELATED APPLICATION

This application claims priority from Korean Patent Application No. 10-2024-0116220 filed on Aug. 28, 2024 in the Korean Intellectual Property Office and all the benefits accruing therefrom under 35 U.S.C. § 119, the contents of which in its entirety are herein incorporated by reference.

### BACKGROUND

The present disclosure relates generally to a semiconductor memory device, and more particularly, to a three-dimensional semiconductor memory device in which electrical characteristics are improved.

It is required to increase the degree of integration of a semiconductor device in order to meet excellent performance and low price, which are required by consumers. Since the degree of integration of the semiconductor device is an important factor that determines the price of a product, an increased degree of integration is particularly required.

In case of a two-dimensional or planar semiconductor device of the related art, since the degree of integration of the two-dimensional or planar semiconductor device is mainly determined by an area occupied by a unit memory cell, the two-dimensional or planar semiconductor device is greatly affected by a level of technology for forming a fine pattern. However, since ultra-high-priced equipment is required for the fine pattern, the degree of integration of the two-dimensional semiconductor device is increasing but still restrictive. Accordingly, three-dimensional semiconductor memory devices with memory cells three-dimensionally arranged have been proposed.

### SUMMARY

An object of the present disclosure is to provide a semiconductor memory device that includes a back gate electrode and a gate electrode, which have their respective materials or physical properties which are different from each other.

The objects of the present disclosure are not limited to those mentioned above and additional objects of the present disclosure, which are not mentioned herein, will be clearly understood by those skilled in the art from the following description of the present disclosure.

According to an example embodiment of the present disclosure, a semiconductor memory device includes: a back gate electrode, which includes a first conductive pattern, on a substrate; a first gate electrode, which includes a second conductive pattern, on the back gate electrode; and a first semiconductor pattern between the back gate electrode and the first gate electrode, wherein the first conductive pattern and the second conductive pattern include their respective materials different from each other, or have their respective physical properties different from each other.

According to an example embodiment of the present disclosure, a semiconductor memory device includes: a plurality of structures stacked on a substrate in a first direction perpendicular to an upper surface of the substrate; and a bit line extending in the first direction, wherein each of the plurality of structures includes a back gate electrode including a first conductive pattern, a first semiconductor pattern on the back gate electrode, a first gate electrode, which includes a second conductive pattern, on the first semiconductor pattern, and a data storage element on the first semiconductor pattern, the bit line is connected to one end of the first semiconductor pattern, the data storage element is connected to the other end of the first semiconductor pattern, and the first conductive pattern and the second conductive pattern include their respective materials different from each other or have their respective physical properties different from each other.

According to an example embodiment of the present disclosure, a semiconductor memory device includes: a plurality of structures stacked on a substrate in a first direction perpendicular to an upper surface of the substrate; and a bit line extending in the first direction, wherein each of the plurality of structures includes a back gate electrode extending in a second direction parallel with the upper surface of the substrate, including a first conductive pattern, a first gate insulating layer on upper and lower surfaces of the back gate electrode, a first gate electrode, which extends in the second direction and includes a second conductive pattern, on the back gate electrode, a second gate insulating layer on a lower surface of the first gate electrode, a first semiconductor pattern, extending in a third direction parallel to the upper surface of the substrate and crossing the second direction, between the back gate electrode and the first gate electrode, and a data storage element on the first semiconductor pattern, the bit line is connected to one end of the first semiconductor pattern, the data storage element is connected to the other end of the first semiconductor pattern, and the first conductive pattern and the second conductive pattern include their respective materials different from each other or have their respective physical properties different from each other.

### BRIEF DESCRIPTION OF THE DRAWINGS

The above and other aspects and features of the present disclosure will become more apparent by describing in detail exemplary embodiments thereof with reference to the attached drawings, wherein like reference numerals (when used) indicate corresponding elements throughout the several views, and in which:

FIG. 1 is an exemplary schematic perspective view illustrating a semiconductor memory device according to some embodiments;

FIG. 2 is an exemplary schematic cross-sectional view illustrating a semiconductor memory device according to some embodiments;

FIG. 3 is an enlarged view illustrating a region R of FIG. 2;

FIGS. 4 and 5 are schematic views illustrating a portion of the first and second conductive patterns of FIG. 2;

FIGS. 6 and 7 are schematic cross-sectional views illustrating a semiconductor memory device according to some embodiments;

FIGS. 8 to 22 are schematic views illustrating intermediate processes in an example method for fabricating a semiconductor memory device according to some embodiments;

FIG. 23 is an exemplary schematic cross-sectional view illustrating a semiconductor memory device according to some embodiments;

FIGS. 24 to 31 are schematic views illustrating intermediate processes in an example method for fabricating a semiconductor memory device according to some embodiments;

FIG. 32 is an exemplary schematic cross-sectional view illustrating a semiconductor memory device according to some embodiments; and

FIGS. 33 to 41 are schematic views illustrating intermediate processes in an example method for fabricating a semiconductor memory device according to some embodiments.

### DETAILED DESCRIPTION

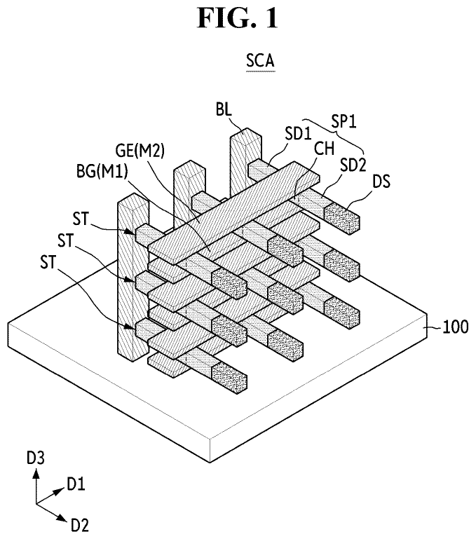

FIG. 1 is an exemplary perspective view illustrating a semiconductor memory device according to some embodiments.

Referring to FIG. 1, a sub-cell array SCA may be disposed on a substrate 100. Although not shown, a plurality of sub-cell arrays SCA may be arranged along a second direction D2.

The substrate 100 may be a bulk silicon or a silicon-on-insulator (SOI). Alternatively, the substrate 100 may be a silicon substrate, or may include another material, for example, silicon germanium on insulator (SGOI), indium antimony, lead tellurite compound, indium arsenide, indium phosphide, gallium arsenide or gallium antimony, but is not limited thereto. The following description will assume that the substrate 100 is a substrate containing silicon.

In this case, a first direction D1, the second direction D2 and a third direction D3 may cross one another. Also, the first direction D1 and the second direction D2 may be parallel with an upper surface of the substrate 100, and the third direction D3 may be perpendicular to the upper surface of the substrate 100. An upper surface, a lower surface, an upper portion and a lower portion may be defined based on the third direction D3.

A structure ST may be stacked on the substrate 100 in the third direction D3. There is no limitation on the number of structures ST that may be included in the sub-cell array SCA.

In some embodiments, the structure ST may include a plurality of first semiconductor patterns SP1, a plurality of data storage elements DS, back gate electrodes BG, and a gate electrode GE.

The first semiconductor pattern SP1 may have a line shape or a bar shape, which extends in the second direction D2. The plurality of semiconductor patterns SP1 positioned at the same level, relative to the upper surface of the substrate 100, may be arranged in the first direction D1. For example, the first semiconductor patterns SP1 of the structure ST may be positioned at the same level and arranged in the first direction D1.

The first semiconductor pattern SP1 may include a semiconductor material such as silicon, germanium or silicon-germanium, although embodiments are not limited thereto. For example, the first semiconductor pattern SP1 may include at least one of polysilicon, polysilicon germanium, single crystal silicon or single crystal silicon-germanium.

Each first semiconductor pattern SP1 may include a channel region CH, a first impurity region SD1 and a second impurity region SD2. The channel region CH may be interposed between the first and second impurity regions SD1 and SD2. The channel region CH, the first impurity region SD1 and the second impurity region SD2 may correspond to a channel of a memory cell transistor, a first source/drain and a second source/drain, respectively. A gate of the memory cell transistor may be connected to the gate electrode GE.

The first and second impurity regions SD1 and SD2 may be regions doped with impurities in the first semiconductor pattern SP1. Therefore, the first and second impurity regions SD1 and SD2 may have n-type or p-type conductivity. The first impurity region SD1 may be formed to be adjacent to a first end of the first semiconductor pattern SP1, and the second impurity region SD2 may be formed to be adjacent to a second end of the first semiconductor pattern SP1. The second end may face the first end in the second direction D2.

Bit lines BL may be conductive patterns (for example, metallic conductive line) extending in a direction (i.e., the third direction D3) perpendicular to the substrate. The bit line BL may have a line shape or a column shape, which extends in the third direction D3. The bit lines BL in one sub-cell array SCA may be arranged in the first direction D1. The bit lines BL adjacent to each other may be spaced apart from each other in the first direction D1.

The bit line BL may include a conductive material, for example, at least one of a doped semiconductor material, a conductive metal nitride, metal or a metal-semiconductor compound, but is not limited thereto.

The first impurity region SD1 may be adjacent to the bit line BL. The first impurity region SD1 may be connected to the bit line BL. The term “connected” (or “connecting,” or like terms, such as “contact” or “contacting”), as may be used herein, is intended to refer to a physical and/or electrical connection between two or more elements, and may include other intervening elements. As used herein, the term “and/or” includes any and all combinations of one or more of the associated listed items. Each bit line BL may be electrically connected to the first impurity region SD1 of the first semiconductor pattern SP1 vertically stacked. The second impurity region SD2 may be adjacent to the data storage element DS. The second impurity region SD2 may be connected to the data storage element DS.

The data storage elements DS may be memory elements capable of storing data. Each of the data storage elements DS may be a memory element using a capacitor, a memory element using a magnetic tunnel junction pattern or a memory element using a variable resistor containing a phase change material.

The back gate electrodes BG may be conductive patterns (e.g., metallic conductive lines) stacked on the substrate in the third direction D3. The back gate electrodes BG may be stacked to be spaced apart from each other along the third direction D3. Each of the back gate electrodes BG may be extended in the first direction D1. The back gate electrodes BG may have a line shape or a bar shape, which is extended in the first direction D1. The back gate electrodes BG may be disposed on at least a portion of an outer circumferential surface of the channel region CH of the first semiconductor pattern SP1. The back gate electrode BG may be extended in the first direction D1 while crossing the first semiconductor pattern SP1 in one structure ST.

The gate electrodes GE may be conductive patterns (e.g., metallic conductive lines) stacked on the substrate in the third direction D3. The gate electrodes GE may be stacked to be spaced apart from each other in the third direction D3. Each of the gate electrodes GE may be extended in the first direction D1. The gate electrodes GE may have a line shape or a bar shape, which is extended in the first direction D1. The gate electrodes GE may be disposed on at least a portion of the outer circumferential surface of the channel region CH of the first semiconductor pattern SP1. The gate electrode GE may be extended in the first direction D1 while crossing the first semiconductor pattern SP1 in one structure ST.

The first semiconductor patterns SP1 of the structure ST may be arranged in the first direction D1, each bit line BL may be connected to each first semiconductor pattern SP1 of the structure ST, and the back gate electrode BG and the gate electrode GE of the structure ST may extend in the first direction D1 to cross the channel region CH of each first semiconductor pattern SP1 of the structure ST. The first semiconductor pattern SP1 may be disposed between the back gate electrode BG and the gate electrode GE.

Each of the back gate electrode BG and the gate electrode GE may include a conductive material. For example, each of the back gate electrode BG and the gate electrode GE may include at least one of a doped semiconductor material (doped silicon, doped silicon-germanium, doped germanium, etc.), a conductive metal nitride (titanium nitride, tantalum nitride, etc.), metal (tungsten, titanium, tantalum, etc.), or a metal-semiconductor compound (tungsten silicide, cobalt silicide, titanium silicide, etc.), but is not limited thereto.

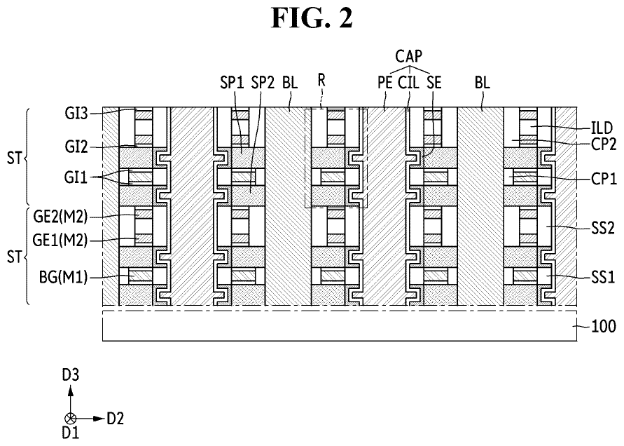

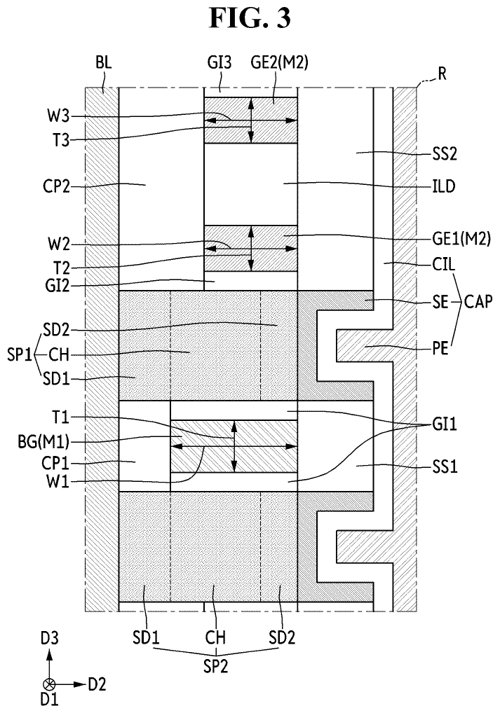

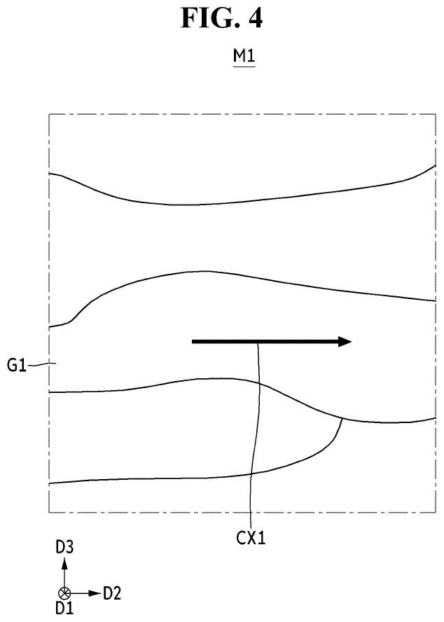

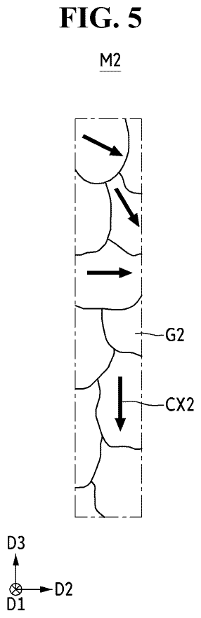

FIG. 2 is an exemplary cross-sectional view illustrating a semiconductor memory device according to some embodiments. FIG. 3 is an enlarged view illustrating a region R of FIG. 2. FIGS. 4 and 5 are views illustrating first and second conductive patterns of FIG. 2. For reference, FIG. 2 is a cross-sectional view illustrating the first and second semiconductor patterns SP1 and SP2 taken along the second direction D2. For convenience of description, a redundant portion of that described with reference to FIG. 1 will be briefly described, and the description will be based on differences from the description of FIG. 1.

Referring to FIG. 2, the semiconductor memory device according to some embodiments includes a substrate 100 and a structure ST stacked on the substrate 100 in the third direction D3. The structure ST may be repeatedly stacked on the substrate 100. Embodiments are not limited to any specific number of structures ST included in the semiconductor memory device.

In some embodiments, the structure ST may include a first semiconductor pattern SP1, a second semiconductor pattern SP2, a back gate electrode BG, a first gate electrode GE1, a second gate electrode GE2, a first gate insulating layer GI1, a second gate insulating layer GI2, a third gate insulating layer GI3, an interlayer insulating layer ILD, a first spacer pattern SS1, a second spacer pattern SS2, a first capping pattern CP1, a second capping pattern CP2, and a capacitor CAP. The gate electrode GE of FIG. 1 may include first and second gate electrodes GE1 and GE2. The data storage element DS of FIG. 1 may be the capacitor CAP.

In the structure ST, the second semiconductor pattern SP2, the back gate electrode BG, the first semiconductor pattern SP1, the first gate electrode GE1, the interlayer insulating layer ILD and the second gate electrode GE2 may be sequentially stacked along the third direction D3. The second semiconductor pattern SP2, the first semiconductor pattern SP1 and the interlayer insulating layer ILD may be sequentially disposed to be spaced apart from one another in the third direction D3.

The first semiconductor pattern SP1 may be disposed between the back gate electrode BG and the first gate electrode GE1. The back gate electrode BG may be disposed on a lower surface of the first semiconductor pattern SP1, and the first gate electrode GE1 may be disposed on an upper surface of the first semiconductor pattern SP1. The interlayer insulating layer ILD may be disposed between the first gate electrode GE1 and the second gate electrode GE2. The first gate electrode GE1 may be disposed on a lower surface of the interlayer insulating layer ILD, and the second gate electrode GE2 may be disposed on an upper surface of the interlayer insulating layer ILD. The second semiconductor pattern SP2 of a first structure may be disposed between the back gate electrode BG of the first structure and the second gate electrode GE2 of a second structure disposed below the first structure. The back gate electrode BG of the first structure may be disposed on an upper surface of the second semiconductor pattern SP2 of the first structure, and the second gate electrode GE2 of the second structure may be disposed on a lower surface of the second semiconductor pattern SP2 of the first structure.

Each of the second semiconductor pattern SP2 and the first semiconductor pattern SP1 may extend in the second direction D2. Each of the second semiconductor pattern SP2 and the first semiconductor pattern SP1 may include a first impurity region SD1, a channel region CH, and a second impurity region SD2. The second semiconductor pattern SP2, and the first end of the first semiconductor pattern SP1, that is, the first impurity region SD1, may be connected to a bit line BL. The second semiconductor pattern SP2 and the second end of the first semiconductor pattern SP1, that is, the second impurity region SD2, may be connected to each of storage electrodes SE.

Each of the second semiconductor pattern SP2 and the first semiconductor pattern SP1 may include a semiconductor material such as silicon, germanium or silicon-germanium, although embodiments are not limited thereto. For example, each of the second semiconductor pattern SP2 and the first semiconductor pattern SP1 may include at least one of polysilicon, polysilicon germanium, single crystal silicon or single crystal silicon-germanium.

In some embodiments, the second semiconductor pattern SP2 and the first semiconductor pattern SP1 may include the same material. In some other embodiments, the second semiconductor pattern SP2 and the first semiconductor pattern SP1 may include their respective materials different from each other.

The interlayer insulating layer ILD may include an insulating material. For example, the interlayer insulating layer ILD may include at least one of a silicon oxide layer, a silicon nitride layer, a silicon oxynitride layer, a carbon-containing silicon oxide layer, a carbon-containing silicon nitride layer or a carbon-containing silicon oxynitride layer, although embodiments are not limited thereto. For example, the interlayer insulating layer ILD may include a silicon oxide layer.

In some embodiments, a length W1 of the back gate electrode BG in the second direction D2 may be different from a length W2 of the first gate electrode GE1 in the second direction D2 and a length W3 of the second gate electrode GE2 in the second direction D2. A portion of the back gate electrode BG may overlap the first gate electrode GE1 and the second gate electrode GE2 in the third direction D3. As used herein, “an element A overlapping an element B in a direction X” (or similar language) means that there is at least one line that extends in the direction X and intersects both the elements A and B. The length W2 of the first gate electrode GE1 in the second direction D2 may be substantially the same as the length W3 of the second gate electrode GE2 in the second direction D2. In this case, “substantially the same” means the same case or the case that there is a difference in the range of deviation occurring during a fabricating process, and may be interpreted as this meaning even in the case that the expression “substantially” is omitted.

In some other embodiments, the length W1 of the back gate electrode BG in the second direction D2 may be substantially the same as the length W2 of the first gate electrode GE1 in the second direction D2 and the length W3 of the second gate electrode GE2 in the second direction D2.

In some embodiments, a thickness T1 of the back gate electrode BG in the third direction D3 may be different from a thickness T2 of the first gate electrode GE1 in the third direction D3 and a thickness T3 of the second gate electrode GE2 in the third direction D3. The thickness T2 of the first gate electrode GE1 in the third direction D3 may be substantially the same as the thickness T3 of the second gate electrode GE2 in the third direction D3.

In some other embodiments, the thickness T1 of the back gate electrode BG in the third direction D3 may be substantially the same as the thickness T2 of the first gate electrode GE1 in the third direction D3 and the thickness T3 of the second gate electrode GE2 in the third direction D3.

In some embodiments, each of the back gate electrode BG, the first gate electrode GE1 and the second gate electrode GE2 may be a single layer. The back gate electrode BG may be formed of a first conductive pattern M1. Each of the first gate electrode GE1 and the second gate electrode GE2 may be formed of a second conductive pattern M2. Each of the first conductive pattern M1 and the second conductive pattern M2 may include at least one of TiN, TiAlC, TiAlN, TiSiN, TiWN, Mo, MoSi, MoSiN, MON, W, Ta, TaN, LaN, Al, Cu, Ru or their compound, although embodiments are not limited thereto.

In some embodiments, the first conductive pattern M1 and the second conductive pattern M2 may include their respective materials different from each other. For example, the first conductive pattern M1 may include TiN, and the second conductive pattern M2 may include TiAlC.

In some embodiments, the first conductive pattern M1 and the second conductive pattern M2 may have their respective physical properties (e.g., shape, dimensions, and/or etc.) different from each other. The physical properties may also include, for example, a composition, a crystal direction (i.e., orientation), and/or an average crystal grain size.

In some embodiments, the first conductive pattern M1 and the second conductive pattern M2 may include the same material, but may have their respective compositions different from each other. For example, when the first conductive pattern M1 and the second conductive pattern M2 include TiN, a composition ratio of Ti and N of the first conductive pattern M1 may be different from a composition ratio of Ti and N of the second conductive pattern M2.

In some embodiments, a shape of a first crystal grain of the first conductive pattern M1 may be different from a shape of a second crystal grain of the second conductive pattern M2. For example, a crystal direction of the first conductive pattern M1 may be different from a crystal direction of the second conductive pattern M2. For example, a size of an average crystal grain of the first conductive pattern M1 may be different from a size of an average crystal grain of the second conductive pattern M2.

For example, referring to FIGS. 4 and 5, the first conductive pattern M1 may include a plurality of first crystal grains G1. A crystal direction CX1 of the first crystal grains G1 may be a direction parallel with the upper surface of the substrate 100. The crystal direction CX1 of the first crystal grains G1 may be a second direction D2. The first crystal grains G1 may be aligned in the second direction D2. The first conductive pattern M1 may have a crystal structure that includes columnar grains G1 extending longitudinally in the second direction D2.

The second conductive pattern M2 may include a plurality of second crystal grains G2. The second crystal grains G2 may have a random crystal direction CX2. The second crystal grains G2 may be aligned in a random direction. The second conductive pattern M2 may have a crystal structure that includes random crystal grains G2.

The average crystal grain size of the first conductive pattern M1 may be an average value of the size of the first crystal grain G1 in the second direction D2, and the average crystal grain size of the second conductive pattern M2 may be an average value of the size of the second crystal grain G2 in the second direction D2. The size of the first crystal grain G1 in the second direction D2 may be greater than the size of the second crystal grain G2 in the second direction D2.

The first conductive pattern M1 and the second conductive pattern M2 may be easily analyzed through Transmission Electron Microscope (TEM), Time-of-Flight Secondary Ion Mass Spectrometry (ToF-SIMS), Transmission Kikuchi Diffraction (TKD), Energy Dispersive X-ray Spectroscopy (EDS), etc.

Referring back to FIGS. 2 and 3, the first gate insulating layer GI1 may extend along upper and lower surfaces of the back gate electrode BG. The second gate insulating layer GI2 may extend along a lower surface of the first gate electrode GE1. The third gate insulating layer GI3 may extend along an upper surface of the second gate electrode GE2. The first gate insulating layer GI1 may be between the back gate electrode BG and the second semiconductor pattern SP2 and between the back gate electrode BG and the first semiconductor pattern SP1. The second gate insulating layer GI2 may be between the first gate electrode GE1 and the first semiconductor pattern SP1. The third gate insulating layer GI3 may be between the second gate electrode GE2 and the second semiconductor pattern SP2. The second gate insulating layer GI2 may not be disposed on an upper surface of the first gate electrode GE1, and the third gate insulating layer G13 may not be disposed on the lower surface of the second gate electrode GE2.

Each of the first to third gate insulating layers GI1, GI2 and GI3 may include at least one of, for example, a high dielectric constant insulating layer, a silicon oxide layer, a silicon nitride layer or a silicon oxynitride layer. The second gate insulating layer GI2 and the third gate insulating layer GI3 may include the same material. In some embodiments, the first gate insulating layer GI1 may include the same material as those of the second and third gate insulating layers GI2 and GI3. In some other embodiments, the first gate insulating layer GI1 may include a material different from those of the second and third gate insulating layers GI2 and GI3.

The first capping pattern CP1 may be between the second semiconductor pattern SP2 and the first semiconductor pattern SP1. The first capping pattern CP1 may be between the first impurity region SD1 of the second semiconductor pattern SP2 and the first impurity region SD1 of the first semiconductor pattern SP1. The first capping pattern CP1 may be between the back gate electrode BG and the bit line BL. The first capping pattern CP1 may spatially separate the back gate electrode BG from the bit line BL.

The second capping pattern CP2 may be between the first semiconductor pattern SP1 of the first structure and the second semiconductor pattern SP2 of the second structure disposed above the first structure. The second capping pattern CP2 may be between the first impurity region SD1 of the first semiconductor pattern SP1 of the first structure SP1 and the first impurity region SD1 of the second semiconductor pattern SP2 of the second structure. The second capping pattern CP2 may spatially separate the first gate electrode GE1 and the second gate electrode GE2 from the bit line BL.

The first spacer pattern SS1 may be disposed on the back gate electrode BG. The first spacer pattern SS1 may be more protruded in the second direction D2 than the second semiconductor pattern SP2 and the first semiconductor pattern SP1. The first spacer pattern SS1 may be disposed between the back gate electrode BG and the capacitor CAP. The back gate electrode BG and the first gate insulating layer GI1 may be disposed between the first capping pattern CP1 and the first spacer pattern SS1.

The second spacer pattern SS2 may be disposed on the first gate electrode GE1 and the second gate electrode GE2. The second spacer pattern SS2 may protrude more in the second direction D2 than the first semiconductor pattern SP1 and the second semiconductor pattern SP2. The second spacer pattern SS2 may be between the first and second gate electrodes GE1 and GE2 and the capacitor CAP. The second spacer pattern SS2 may be between the interlayer insulating layer ILD and the capacitor CAP. The first gate electrode GE1, the second gate insulating layer GI2, the interlayer insulating layer ILD, the second gate electrode GE2 and the third gate insulating layer GI3 may be between the second capping pattern CP2 and the second spacer pattern SS2.

Each of the first capping pattern CP1, the second capping pattern CP2, the first spacer pattern SS1 and the second spacer pattern SS2 may include at least one of, for example, a silicon oxide layer, a silicon nitride layer, a silicon oxynitride layer, a carbon-containing silicon oxide layer, a carbon-containing silicon nitride layer or a carbon-containing silicon oxynitride layer, although embodiments are not limited thereto. The second capping pattern CP2, the first spacer pattern SS1 and the second spacer pattern SS2 may include the same material. In some embodiments, the first capping pattern CP1 may include a material different from those of the second capping pattern CP2 and the first and second spacer patterns SS1 and SS2.

The capacitor CAP may include a capacitor dielectric layer CIL, a plurality of storage electrodes SE, and a plate electrode PE. The capacitor CAP may be defined by each storage electrode SE.

The storage electrode SE may be formed in each of the first and second semiconductor patterns SP1 and SP2. Each storage electrode SE may be disposed between the first spacer pattern SS1 and the second spacer pattern SS2, which are adjacent to each other in the third direction D3. The storage electrodes SE included in the respective capacitors CAP are separated from each other. The storage electrodes SE, which are adjacent to each other in the third direction D3 in one structure ST, may be separated from each other by the first spacer pattern SS1. The storage electrodes SE, which are adjacent to each other in the third direction D3, may be separated from each other by the first spacer pattern SS1 or the second spacer pattern SS2.

The capacitor dielectric layer CIL may be disposed on the storage electrode SE. The capacitor dielectric layer CIL may extend along a profile of the plurality of storage electrodes SE. The plate electrode PE may be disposed on the capacitor dielectric layer CIL. The capacitor dielectric layer CIL and the plate electrode PE may be sequentially disposed on the storage electrode SE. The capacitor dielectric layer CIL may be between the first spacer pattern SS1 and the plate electrode PE and between the second spacer pattern SS2 and the plate electrode PE.

Each of the storage electrode SE and the plate electrode PE may include, for example, a doped semiconductor material, a conductive metal nitride (e.g., titanium nitride, tantalum nitride, niobium nitride, or tungsten nitride), metal (e.g., ruthenium, iridium, titanium, niobium, tungsten, cobalt, molybdenum or tantalum), and a conductive metal oxide (e.g., iridium oxide or niobium oxide), but is not limited thereto. For example, the storage electrode SE may include a conductive metal nitride, metal and a conductive metal oxide. The conductive metal nitride, the metal and the conductive metal oxide may be included in a metallic conductive layer.

The capacitor dielectric layer CIL may include, for example, a high dielectric constant material (e.g., hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobate, or their combination). In the semiconductor memory device according to some embodiments, the capacitor dielectric layer CIL may include a stacked layer structure in which zirconium oxide, aluminum oxide and zirconium oxide are sequentially stacked. In the semiconductor memory device according to some embodiments, the capacitor dielectric layer CIL may include hafnium (Hf).

The semiconductor memory device according to some embodiments includes a back gate electrode BG. A voltage different from a voltage applied to the first and second gate electrodes GE1 and GE2 may be applied to the back gate electrode BG. Since the channel regions CH of the memory cell transistor may be a floating body and the back gate electrode BG may control charges accumulated in the channel region CH, for example, holes, a floating body effect may be suppressed or controlled, and a threshold voltage of the memory cell transistors may be prevented from being varied. Thus, the back gate electrode BG may improve electrical characteristics of the memory cell transistors.

In an example, the back gate electrode BG may be independently and individually controlled in consideration of an interlayer characteristic distribution of memory cell transistors disposed in each layer. Alternatively, at least some of the back gate electrodes BG may be electrically connected to each other and controlled together.

Also, in the semiconductor memory device according to some embodiments, each of the back gate electrode BG and the first and second gate electrodes GE1 and GE2 include first and second conductive patterns M1 and M2, which may include different materials or have different physical properties. That is, since materials of the back gate electrode BG and the first and second gate electrodes GE1 and GE2 may be adjusted respectively, gate controllability may be increased.

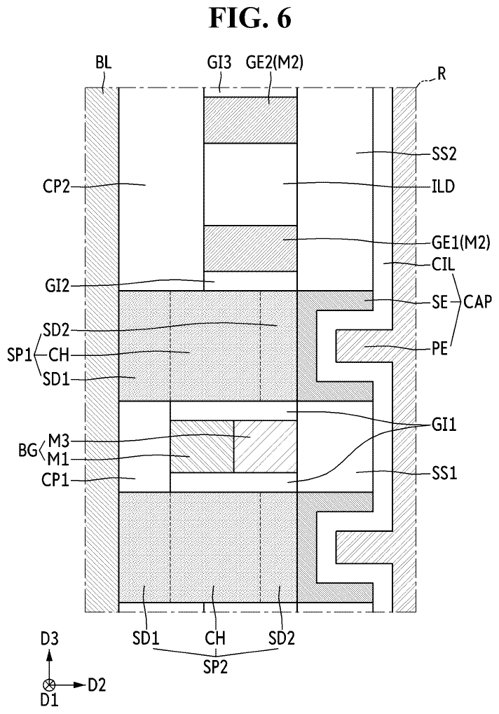

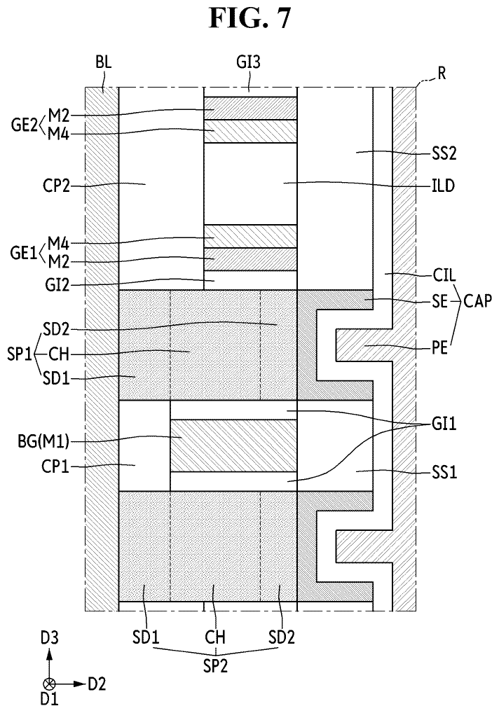

FIGS. 6 and 7 are views illustrating a semiconductor memory device according to some embodiments. For reference, FIGS. 6 and 7 are enlarged views illustrating a region R of FIG. 2. For convenience of description, a redundant portion of that described with reference to FIGS. 1 to 5 will be briefly described, and the description will be based on differences from the description of FIGS. 1 to 5.

Referring to FIG. 6, in the semiconductor memory device according to some embodiments, the back gate electrode BG may be a multi-layer structure. For example, the back gate electrode BG may include a first conductive pattern M1 and a third conductive pattern M3 contacting each other in the second direction D2.

For example, the third conductive pattern M3 may be between the first conductive pattern M1 and the first spacer pattern SS1. The first gate insulating layer GI1 may extend in the second direction D2 along upper and lower surfaces of the first conductive pattern M1 and the third conductive pattern M3.

The third conductive pattern M3 may include at least one of TIN, TiAlC, TiAlN, TiSiN, TiWN, Mo, MoSi, MoSiN, MON, W, Ta, TaN, LaN, Al, Cu, Ru or their compound, although embodiments are not limited thereto.

In some embodiments, the first conductive pattern M1 and the third conductive pattern M3 may include their respective materials different from each other. For example, the first conductive pattern M1 may include TiN, and the third conductive pattern M3 may include TiAlC.

In some embodiments, the first conductive pattern M1 and the third conductive pattern M3 may have their respective physical properties different from each other.

In some embodiments, the first conductive pattern M1 and the third conductive pattern M3 may include the same material, but may have their respective compositions different from each other.

In some embodiments, a shape of a first crystal grain of the first conductive pattern M1 may be different from a shape of a second crystal grain of the third conductive pattern M3. For example, a crystal direction of the first conductive pattern M1 may be different from a crystal direction of the third conductive pattern M3. For example, a size of an average crystal grain of the first conductive pattern M1 may be different from a size of an average crystal grain of the third conductive pattern M3.

Referring to FIG. 7, in the semiconductor memory device according to some embodiments, each of the first gate electrode GE1 and the second gate electrode GE2 may be a multi-layer structure. For example, each of the first gate electrode GE1 and the second gate electrode GE2 may include a second conductive pattern M2 and a fourth conductive pattern M4 contacting each other in the third direction D3.

For example, the fourth conductive pattern M4 may be between the second conductive pattern M2 and the interlayer insulating layer ILD. The first gate electrode GE1 may include the second conductive pattern M2 and the fourth conductive pattern M4 on an upper surface of the second conductive pattern M2. The second gate electrode GE2 may include the fourth conductive pattern M4 and the second conductive pattern M2 on an upper surface of the fourth conductive pattern M4.

The fourth conductive pattern M4 may include at least one of TIN, TiAlC, TiAlN, TiSiN, TiWN, Mo, MoSi, MoSiN, MON, W, Ta, TaN, LaN, Al, Cu, Ru or their compound, although embodiments are not limited thereto.

In some embodiments, the second conductive pattern M2 and the fourth conductive pattern M4 may have their respective materials different from each other.

In some embodiments, the second conductive pattern M2 and the fourth conductive pattern M4 may have their respective physical properties different from each other.

In some embodiments, the second conductive pattern M2 and the fourth conductive pattern M4 may include the same material, but may have their respective compositions different from each other.

In some embodiments, a shape of a first crystal grain of the second conductive pattern M2 may be different from a shape of a second crystal grain of the fourth conductive pattern M4. For example, a crystal direction of the second conductive pattern M2 may be different from a crystal direction of the fourth conductive pattern M4. For example, a size of an average crystal grain of the second conductive pattern M2 may be different from a size of an average crystal grain of the fourth conductive pattern M4.

In some other embodiments, each of the back gate electrode BG, the first gate electrode GE1 and the second gate electrode GE2 may be a multi-layer structure.

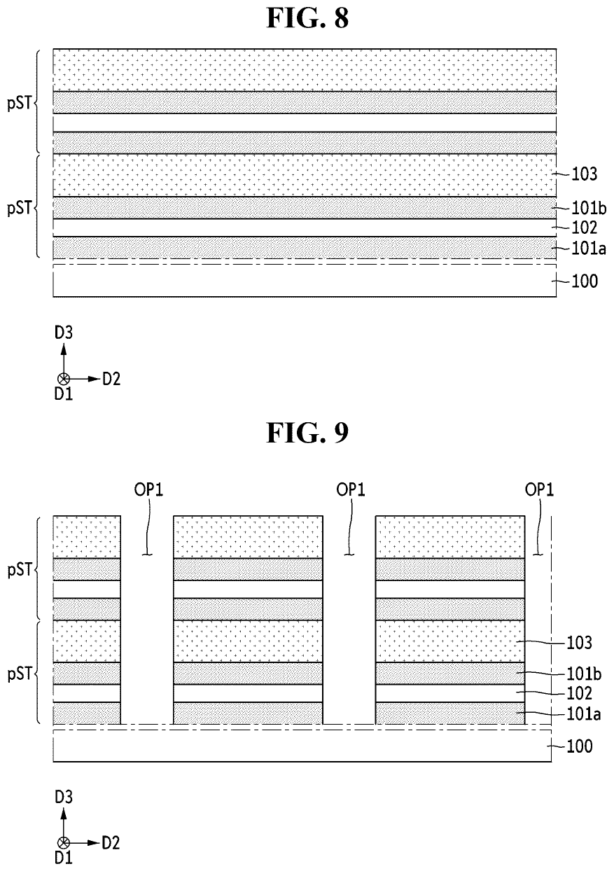

FIGS. 8 to 22 are schematic views illustrating intermediate processes in an example method for fabricating a semiconductor memory device according to some embodiments. For convenience of description, a redundant portion of that described with reference to FIGS. 1 to 6 will be briefly described, and the description will be based on differences from the description of FIGS. 1 to 6.

Referring to FIG. 8, a preliminary structure pST, which is repeatedly stacked along the third direction D3, may be formed on the substrate 100. The preliminary structure pST may be stacked on the substrate 100 along the third direction D3. The number of the preliminary structures pST is not limited to the example of FIG. 8.

In some embodiments, the preliminary structure pST may include a (1-1)th material layer 101a, a second material layer 102, a (1-2)th material layer 101b and a third material layer 103, which are sequentially stacked in the third direction D3.

The (1-1)th material layer 101a and the (1-2)th material layer 101b may include the same material. The (1-1)th material layer 101a and the (1-2)th material layer 101b may include, for example, silicon, germanium, silicon-germanium or indium gallium zinc oxide (IGZO), although embodiments are not limited thereto. The second material layer 102 and the third material layer 103 may be formed of a material having etch selectivity with respect to the (1-1)th material layer 101a and the (1-2)th material layer 101b. The second material layer 102 may be formed of a material having etch selectivity with respect to the third material layer 103.

Referring to FIG. 9, one or more first openings OP1 extending in the third direction D3 through a plurality of preliminary structures pST may be formed. The first openings OP1 may be spaced apart from each other in the second direction D2.

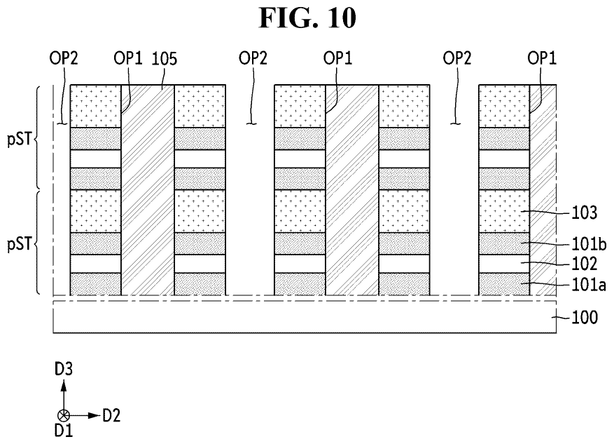

Referring to FIG. 10, a supporter 105 for filling the first openings OP1 may be formed. The term “filling” (or “fill,” or like terms) is intended to refer to either completely filling a defined space (e.g., the first openings OP1) or partially filling the defined space; that is, the defined space need not be entirely filled but may, for example, be partially filled or have voids or other spaces throughout. The supporter 105 may be formed of a material having etch selectivity with respect to the second material layer 102 and the third material layer 103.

One or more second openings OP2 extending in the third direction D3 through the plurality of preliminary structures pST may be formed. Each of the second openings OP2 may be formed between the supporters 105 adjacent to each other in the second direction D2.

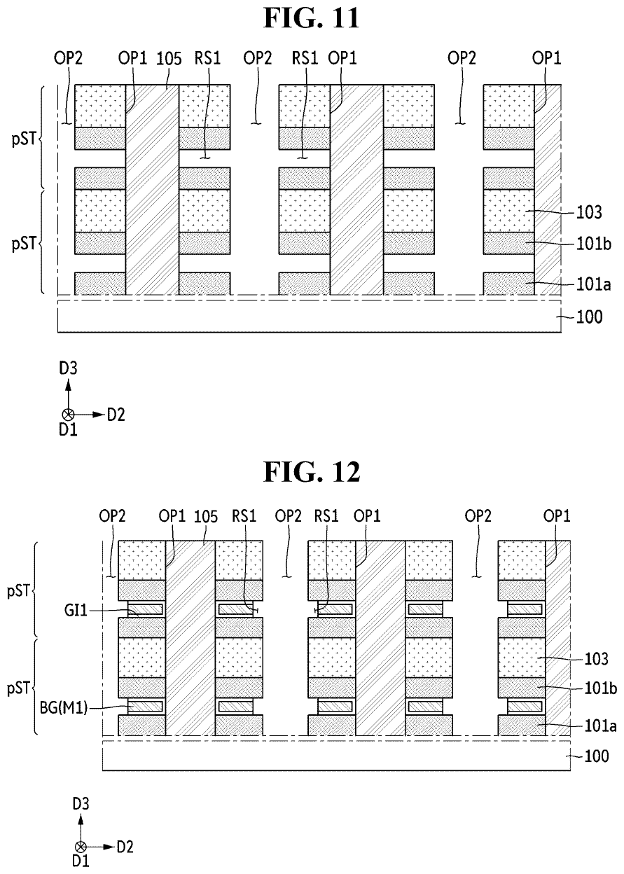

Referring to FIGS. 10 and 11, the second material layer 102 exposed by the second opening OP2 may be removed so that a first recess region RS1 between the (1-1)th material layer 101a and the (1-2)th material layer 101b, which are adjacent to each other, may be formed. The term “exposed” (or “expose,” or like terms) may be used herein to describe relationships between elements and/or with reference to intermediate processes in fabricating a semiconductor device, but may not require exposure of a particular element in the completed device. Likewise, the term “not exposed” may be used to described relationships between elements and/or with reference to intermediate processes in fabricating a semiconductor device, but may not require a particular element to be unexposed in the completed device.

The second material layer 102 may be isotropically etched by an etching process having etch selectivity with respect to the (1-1)th material layer 101a, the (1-2)th material layer 101b, the third material layer 103 and the supporter 105. When the second material layer 102 is removed, the (1-1)th material layer 101a, the (1-2)th material layer 101b and the third material layer 103 may be supported by the supporter 105.

A thickness of the first recess region RS1 in the third direction D3, that is, a distance between the (1-1)th material layer 101a and the (1-2)th material layer 101b, which are adjacent to each other, may be substantially the same as a thickness of the second material layer 102.

Referring to FIGS. 11 and 12, a first gate insulating layer GI1 and a back gate electrode BG, which fill a portion of the first recess region RS1, may be formed. For example, the back gate electrode BG may include a first conductive pattern M1.

For example, the first gate insulating layer GI1 extending along the first recess region RS1 and the second opening OP2 may be formed. A preliminary conductive pattern for filling the first recess region RS1 and the second opening OP2 may be formed on the first gate insulating layer GI1. The first gate insulating layer GI1 and the preliminary conductive layer may be partially etched to form the first gate insulating layer GI1 and the back gate electrode BG, which fill a portion of the first recess region RS1. The first gate insulating layer GI1 may extend along an upper surface of the back gate electrode BG, and a side and a lower surface of the back gate electrode BG, which are directed toward the supporter 105. Partially etching the first gate insulating layer G1 and the preliminary conductive layer may be performed by an etch-back technique.

Since a thickness of the first recess region RS1 in the third direction D3 varies depending on a thickness of the second material layer 102 (see FIG. 10) in the third direction D3, the thickness of the second material layer 102 in the third direction D3 may be adjusted so that a thickness of the back gate electrode BG in the third direction D3, which is formed in the first recess region RS1, may be adjusted. The thickness of the second material layer 102 may be, for example, about 10 angstroms (Å) to 600 Å.

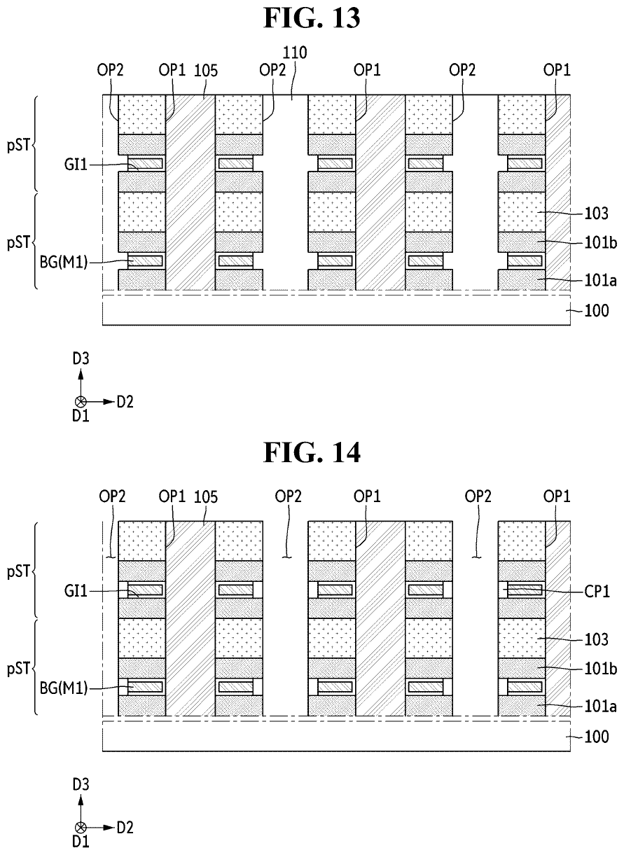

Referring to FIGS. 12 and 13, a first gap fill layer 110 for filling a portion of the first recess region RS1 and the second opening OP2 may be formed. The first gap fill layer 110 may be made of an insulating material having etching selectivity with respect to the (1-1)th material layer 101a, the (1-2)th material layer 101b and the third material layer 103.

Referring to FIGS. 13 and 14, a portion of the first gap fill layer 110 in the second opening OP2 may be removed so that the first capping pattern CP1 for filling the first recess region RS1 may be formed. Removing a portion of the first gap fill layer 110 may be performed by an etch-back technique. A side surface of the first capping pattern CP1 may be coplanar in the third direction D3 with side surfaces of the (1-1)th material layer 101a and the (1-2)th material layer 101b.

The first capping pattern CP1 may be a first gap fill layer 110 for filling the first recess region RS1. The first capping pattern CP1 may be formed between the (1-1)th material layer 101a and the (1-2)th material layer 101b, which are adjacent to each other. The first capping pattern CP1 may fill the first recess region RS1 (see FIGS. 11 and 12) on the first gate insulating layer GI1 and the back gate electrode BG.

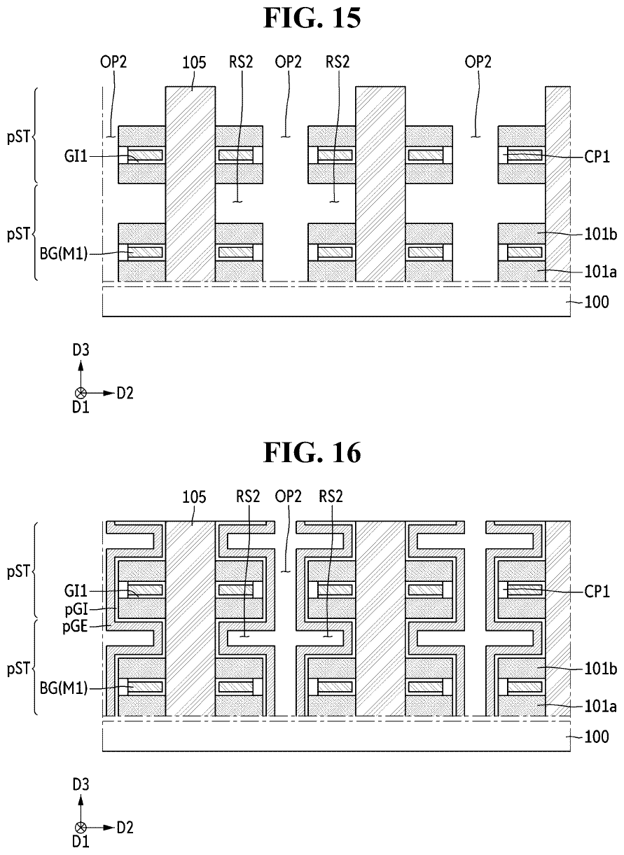

Referring to FIGS. 14 and 15, the third material layer 103 exposed by the second opening OP2 may be removed so that a second recess region RS2 may be formed between the (1-2)th material layer 101b and the (1-1)th material layer 101a, which are adjacent to each other. The third material layer 103 may be isotropically etched by an etching process having etch selectivity with respect to the (1-1)th material layer 101a, the (1-2)th material layer 101b, the supporter 105 and the first capping pattern CP1.

A thickness of the second recess region RS2 in the third direction D3, that is, a distance between the (1-2)th material layer 101b and the (1-1)th material layer 101a, which are adjacent to each other, may be substantially the same as a thickness of the third material layer 103.

Referring to FIGS. 15 and 16, a preliminary gate insulating layer pGI extending along the second recess region RS2 and the second opening OP2 may be formed. A preliminary gate electrode pGE extending along the preliminary gate insulating layer pGI may be formed on the preliminary gate insulating layer pGI. The preliminary gate insulating layer pGI and the preliminary gate electrode pGE may partially fill the second recess region RS2 and the second opening OP2. For example, the preliminary gate electrode pGE may include a second conductive pattern M2.

Since the thickness of the second recess region RS2 in the third direction D3 varies depending on the thickness of the third material layer 103 in the third direction D3, the thickness of the third material layer 103 may be adjusted so that a thickness of the preliminary gate electrode pGE, which will later become the first and second gate electrodes GE1 and GE2 in the second recess region RS2, may be adjusted. The thickness of the third material layer 103 may be, for example, about 10 Å to 600 Å.

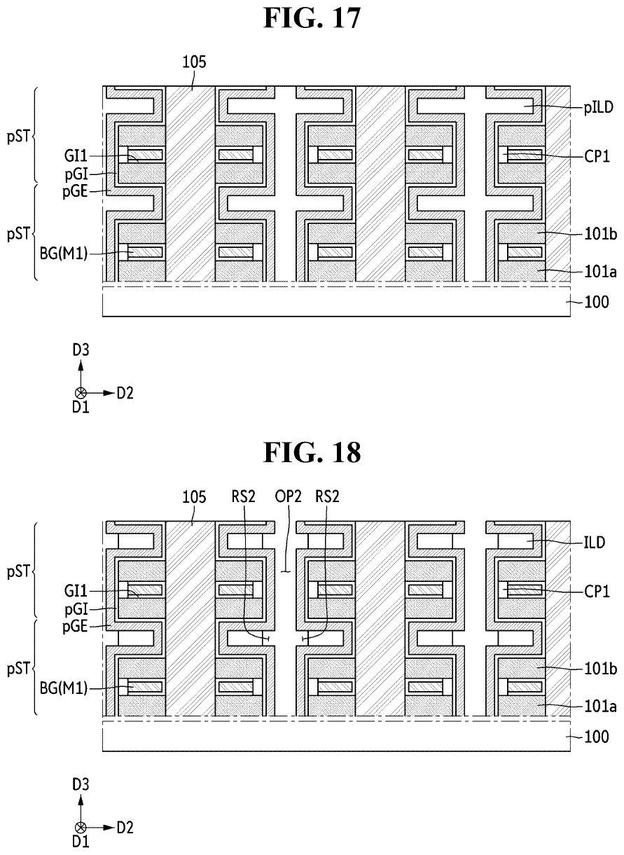

Referring to FIGS. 16 and 17, a preliminary interlayer insulating layer pILD for filling the second recess region RS2 and the second opening OP2 may be formed on the preliminary gate electrode pGE. The preliminary interlayer insulating layer pILD may fill a space between the preliminary gate electrodes pGE, which are adjacent to each other in the third direction D3, in the second recess region RS2.

Referring to FIGS. 17 and 18, a portion of the preliminary interlayer insulating layer pILD filled in the second recess region RS2 and the preliminary interlayer insulating layer pILD in the second opening OP2 may be removed to form the interlayer insulating layer ILD.

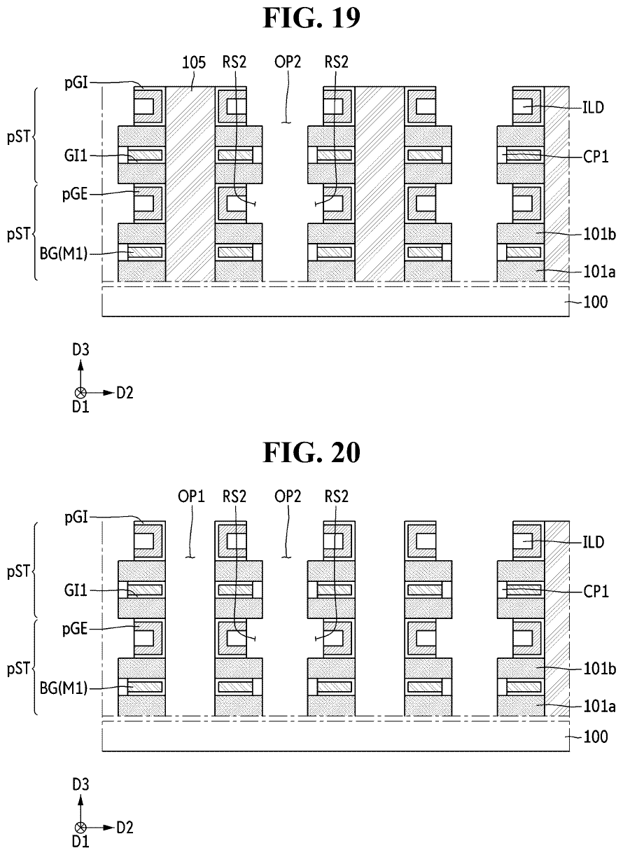

Referring to FIG. 19, the preliminary gate insulating layer pGI and the preliminary gate electrode pGE, which extend along a sidewall of the second opening OP2, may be etched. Therefore, the preliminary gate insulating layer pGI and the preliminary gate electrode pGE, which fill a portion of the second recess region RS2, may remain. When the preliminary gate insulating layer pGI and the preliminary gate electrode pGE are etched, the first gate insulating layer GI1 and the back gate electrode BG may not be etched by the first capping pattern CP1. Etching a portion of the preliminary gate insulating layer pGI and the preliminary gate electrode pGE may be performed by etch-back technique.

Referring to FIGS. 19 and 20, the supporter 105 may be removed so that the first opening (OP1 of FIG. 9) may be formed again. The first gate insulating layer GI1 and the preliminary gate insulating layer pGI may be exposed by the first opening OP1.

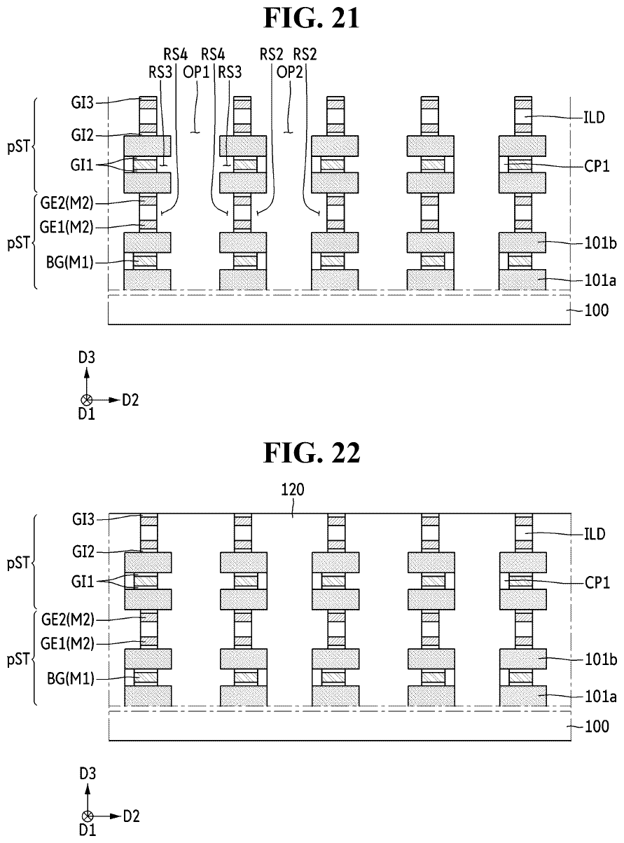

Referring to FIGS. 20 and 21, a portion of the first gate insulating layer GI1 and the back gate electrode BG may be removed through the first opening OP1, so that a third recess region RS3 may be formed between the (1-1)th material layer 101a and the (1-2)th material layer 101b, which are adjacent to each other in the third direction D3. The first gate insulating layer GI1 may be formed on the upper and lower surfaces of the back gate electrode BG.

A portion of the preliminary gate insulating layer pGI and the preliminary gate electrode pGE may be removed through the first opening OP1, so that a fourth recess region RS4 may be formed between the (1-2)th material layer 101b and the (1-1)th material layer 101a, which are adjacent to each other. A portion of the preliminary gate insulating layer pGI and the preliminary gate electrode pGE may be removed through the first opening OP1, so that the first and second gate electrodes GE1 and GE2, which are spaced apart from each other by the interlayer insulating layer ILD, the second gate insulating layer GI2 on the lower surface of the first gate electrode GE1, and the third gate insulating layer GI3 on the upper surface of the second gate electrode GE2 may be formed. Etching a portion of the preliminary gate insulating layer pGI and the preliminary gate electrode pGE may be performed by an etch-back technique.

Referring to FIGS. 21 and 22, a second gap fill layer 120 for filling the first opening OP1, the second opening OP2, the second recess region RS2, the third recess region RS3 and the fourth recess region RS4 may be formed.

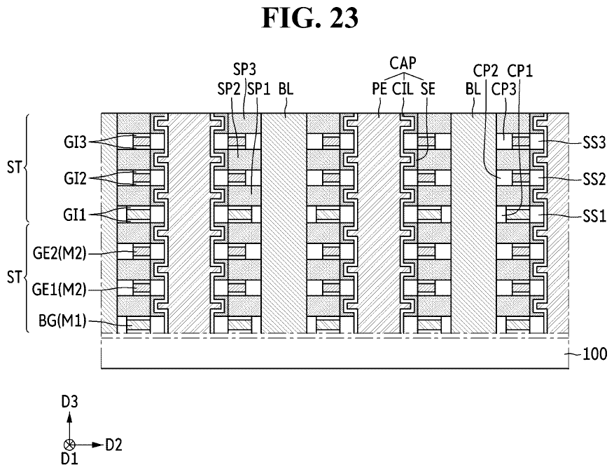

Referring to FIGS. 22 and 23, the second gap fill layer 120 in the first opening OP1 and the second opening OP2 may be removed so that a second capping pattern CP2, a first spacer pattern SS1 and a second spacer pattern SS2 may be formed. Removing a portion of the second gap fill layer 120 may be performed by an etch-back technique.

The second capping pattern CP2 may be a second gap fill layer 120 for filling the second recess region RS2. The second capping pattern CP2 may be formed between the (1-2)th material layer 101b and the (1-1)th material layer 101a, which are adjacent to each other in the third direction D3. The second capping pattern CP2 may fill the second recess region RS2 on the second gate insulating layer GI2, the first gate electrode GE1, the interlayer insulating layer ILD and the second gate electrode GE2.

The first spacer pattern SS1 may be a second gap fill layer 120 for filling the third recess region RS3. The first spacer pattern SS1 may be formed between the (1-1)th material layer 101a and the (1-2)th material layer 101b, which are adjacent to each other in the third direction D3. The first spacer pattern SS1 may fill the third recess region RS3 on the first gate insulating layer GI1 and the back gate electrode BG.

The second spacer pattern SS2 may be a second gap fill layer 120 for filling the fourth recess region RS4. The second spacer pattern SS2 may be formed between the (1-2)th material layer 101b and the (1-1)th material layer 101a, which are adjacent to each other. The second spacer pattern SS2 may fill the fourth recess region RS4 on the second gate insulating layer GI2, the first gate electrode GE1, the interlayer insulating layer ILD and the second gate electrode GE2.

Lengths of the first capping pattern CP1, the second capping pattern CP2, the first spacer pattern SS1 and the second spacer pattern SS2 in the second direction D2 may be adjusted so that lengths of the back gate electrode BG and the first and second gate electrodes GE1 and GE2 in the second direction D2 may be adjusted. The lengths of the back gate electrode BG and the first and second gate electrodes GE1 and GE2 in the second direction D2 may be, for example, about 10 Å to 600 Å.

Subsequently, a portion of the (1-1)th material layer 101a and the (1-2)th material layer 101b may be removed through the first opening OP1 so that a first semiconductor pattern SP1 and a second semiconductor pattern SP2 may be formed. The first spacer pattern SS1 and the second spacer pattern SS2 may protrude (i.e., extend) in the second direction D2 more than the first semiconductor pattern SP1 and the second semiconductor pattern SP2. A gap may be formed between the first spacer pattern SS1 and the second spacer pattern SS2.

A capacitor CAP may be formed in the first opening OP1. A storage electrode SE may be formed in the gap.

A bit line BL may be formed in the second opening OP2.

In a method for fabricating a semiconductor memory device according to some embodiments, the back gate electrode BG may be formed through a separate process from the first and second gate electrodes GE1 and GE2. Therefore, each of the back gate electrode BG and the first and second gate electrodes GE1 and GE2 may be formed of a suitable material, and may include various film materials. Also, there may be various relationships between the length of the back gate electrode BG in the second direction D2 and the length of the first and second gate electrodes GE1 and GE2 in the second direction D2, and there may be various relationships between the thickness of the back gate electrode BG in the third direction D3 and the thickness of the first and second gate electrodes GE1 and GE2 in the third direction D3.

The first gate insulating layer GI1 may be formed through a separate process from the second and third gate insulating layers GI2 and GI3. Therefore, each of the first to third gate insulating layers GI1, GI2 and GI3 may be formed of a suitable material. Also, there may be various relationships between the thickness of the first gate insulating layer GI1 and the thickness of the second and third gate insulating layers GI2 and G13 in the third direction D3.

The first capping pattern CP1 and the second capping pattern CP2 may be formed through a separate process. Therefore, each of the first and second capping patterns CP1 and CP2 may be formed of a suitable material. Also, there may be various relationships between the length of the first capping pattern CP1 in the second direction D2 and the length of the second capping pattern CP2 in the second direction D2, and there may be various relationships between the thickness of the first capping pattern CP1 in the third direction D3 and the thickness of the second capping pattern CP2 in the third direction D3.

FIG. 23 is an exemplary schematic cross-sectional view illustrating a semiconductor memory device according to some embodiments. For reference, FIG. 23 is a cross-sectional view illustrating the first to third semiconductor patterns SP1, SP2 and SP3 taken along the second direction D2.

Referring to FIG. 23, in the semiconductor memory device according to some embodiments, the structure ST may include a first semiconductor pattern SP1, a second semiconductor pattern SP2, a third semiconductor pattern SP3, a back gate electrode BG, a first gate electrode GE1, a second gate electrode GE2, a first gate insulating layer GI1, a second gate insulating layer GI2, a third gate insulating layer G13, a first spacer pattern SS1, a second spacer pattern SS2, a third spacer pattern SS3, a first capping pattern CP1, a second capping pattern CP2, a third capping pattern CP3, and a capacitor CAP. In the structure ST, the back gate electrode BG, the first semiconductor pattern SP1, the first gate electrode GE1, the second semiconductor pattern SP2, the second gate electrode GE2 and the third semiconductor pattern SP3 may be sequentially stacked along the third direction D3. The first semiconductor pattern SP1, the second semiconductor pattern SP2 and the third semiconductor pattern SP3 may be sequentially spaced apart from one another along the third direction D3.

The first semiconductor pattern SP1 may be between the back gate electrode BG and the first gate electrode GE1. The back gate electrode BG may be disposed on the lower surface of the first semiconductor pattern SP1, and the first gate electrode GE1 may be disposed on the upper surface of the first semiconductor pattern SP1. The second semiconductor pattern SP2 may be between the first gate electrode GE1 and the second gate electrode GE2. The first gate electrode GE1 may be disposed on the lower surface of the second semiconductor pattern SP2, and the second gate electrode GE2 may be disposed on the upper surface of the second semiconductor pattern SP2. The third semiconductor pattern SP3 may be between the second gate electrode GE2 of the first structure and the back gate electrode BG of the second structure disposed above the first structure. The second gate electrode GE2 of the first structure may be disposed on the lower surface of the third semiconductor pattern SP3 of the first structure, and the back gate electrode BG of the second structure may be disposed on an upper surface of the third semiconductor pattern SP3 of the first structure.

Each of the first to third semiconductor patterns SP1, SP2 and SP3 may extend in the second direction D2. Each of the first to third semiconductor patterns SP1, SP2 and SP3 may include a first impurity region, a channel region and a second impurity region. The first impurity region of each of the first to third semiconductor patterns may be electrically connected to the bit line BL. The second impurity region of each of the first to third semiconductor patterns SP1, SP2 and SP3 may be electrically connected to each storage electrode SE.

The third semiconductor pattern SP3 may include a semiconductor material such as silicon, germanium or silicon-germanium, although embodiments are not limited thereto. For example, the third semiconductor pattern SP3 may include at least one of polysilicon, polysilicon germanium, single crystal silicon or single crystal silicon-germanium. In some embodiments, the first to third semiconductor patterns SP1, SP2 and SP3 may include the same material.

The second gate insulating layer GI2 may extend along the lower and upper surfaces of the first gate electrode GE1. The third gate insulating layer GI3 may extend along the lower and upper surfaces of the second gate electrode GE2. The first gate insulating layer GI1 may be between the back gate electrode BG and the first semiconductor pattern SP1 and between the back gate electrode BG and the third semiconductor pattern SP3. The second gate insulating layer GI2 may be between the first gate electrode GE1 and the first semiconductor pattern SP1 and between the first gate electrode GE1 and the second semiconductor pattern SP2. The third gate insulating layer GI3 may be between the second gate electrode GE2 and the second semiconductor pattern SP2 and between the second gate electrode GE2 and the third semiconductor pattern SP3.

The second capping pattern CP2 may be between the first semiconductor pattern SP1 and the second semiconductor pattern SP2. The second capping pattern CP2 may be between the first gate electrode GE1 and the bit line BL. The third capping pattern CP3 may be between the second semiconductor pattern SP2 and the third semiconductor pattern SP3. The third capping pattern CP3 may be between the second gate electrode GE2 and the bit line BL.

The second spacer pattern SS2 may be between the first semiconductor pattern SP1 and the second semiconductor pattern SP2. The second spacer pattern SS2 may be between the first gate electrode GE1 and the capacitor CAP. The third spacer pattern SS3 may be between the second semiconductor pattern SP2 and the third semiconductor pattern SP3. The third spacer pattern SS3 may be between the second gate electrode GE2 and the capacitor CAP. The first to third spacer patterns SS1, SS2 and SS3 may protrude in the second direction D2 more than the first to third semiconductor patterns SP1, SP2 and SP3.

The storage electrode SE may be formed on each of the first to third semiconductor patterns SP1, SP2 and SP3. Each storage electrode SE may be between the first spacer pattern SS1 and the second spacer pattern SS2, which are adjacent to each other in the third direction D3, between the second spacer pattern SS2 and the third spacer pattern SS3, which are adjacent to each other in the third direction D3, and between the third spacer pattern SS3 and the first spacer pattern SS1, which are adjacent to each other in the third direction D3. The storage electrodes SE included in each capacitor CAP are separated from each other. The storage electrodes SE, which are adjacent to each other in the third direction D3 in one structure ST, may be separated from each other by the first spacer pattern SS1, the second spacer pattern SS2 or the third spacer pattern SS3.

Each of the back gate electrode BG and the first and second gate electrodes GE1 and GE2 may be a single layer or a multi-layer. For example, the back gate electrode BG may include a first conductive pattern M1 and a third conductive pattern.

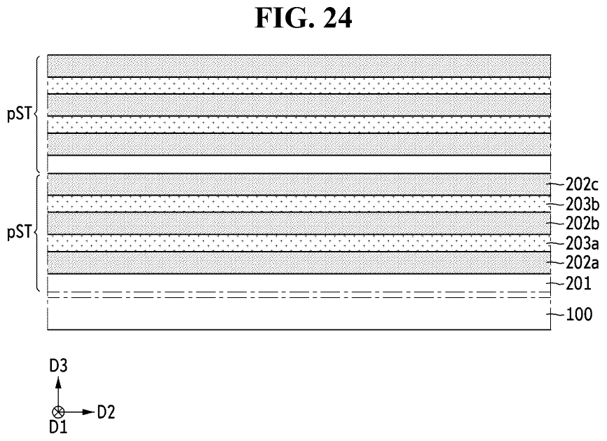

FIGS. 24 to 31 are schematic views illustrating intermediate processes in an example method for fabricating a semiconductor memory device according to some embodiments. For convenience of description, a redundant portion of that described with reference to FIGS. 1 to 23 will be briefly described, and the description will be based on differences from the description of FIGS. 1 to 23.

Referring to FIG. 24, a preliminary structure pST, which is repeatedly stacked along the third direction D3, may be formed on a substrate 100. The preliminary structure pST may include a first material layer 201, a (2-1)th material layer 202a, a (3-1)th material layer 203a, a (2-2)th material layer 202b, a (3-2)th material layer 203b and a (2-3)th material layer 202c, which are sequentially stacked in the third direction D3.

The (2-1)th, (2-2)th and (2-3)th material layers 202a, 202b and 202c may include the same material, and the (3-1)th and (3-2)th material layers 203a and 203b may include the same material. The (2-1)th, (2-2)th and (2-3)th material layers 202a, 202b and 202c may include a material different from the (3-1)th and (3-2)th material layers 203a and 203b. The (2-1)th, (2-2)th and (2-3)th material layers 202a, 202b and 202c may include, for example, silicon, germanium, silicon-germanium or indium gallium zinc oxide (IGZO). The first material layer 201 may be formed of a material having etch selectivity with respect to the (2-1)th, (2-2)th and (2-3)th material layers 202a, 202b and 202c and the (3-1)th and (3-2)th material layers 203a and 203b. The (2-1)th, (2-2)th and (2-3)th material layers 202a, 202b and 202c may be formed of a material having etch selectivity with respect to the (3-1)th and (3-2)th material layers 203a and 203b.

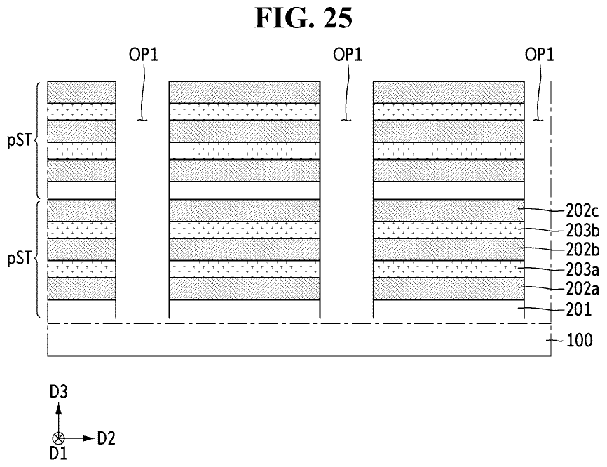

Referring to FIG. 25, one or more first openings OP1 extending in the third direction D3 through a plurality of preliminary structures pST may be formed.

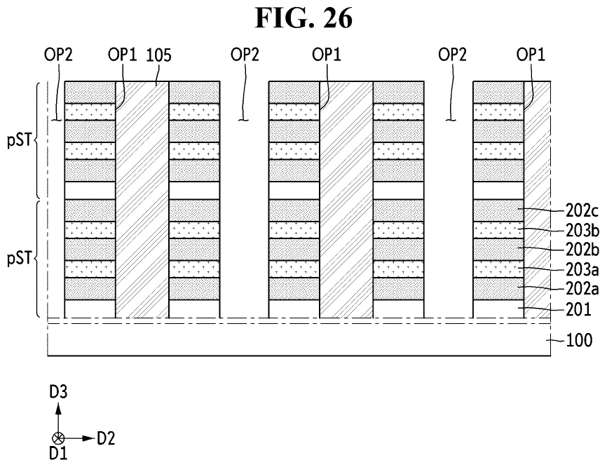

Referring to FIG. 26, a supporter 105 for filling the first opening OP1 may be formed. The supporter 105 may be formed of a material having etch selectivity with respect to the second material layer 102 and the third material layer 103.

One or more second openings OP2 extending in the third direction D3 through the plurality of preliminary structures pST may be formed. Each of the second openings OP2 may be formed between the supporters 105 adjacent to each other in the second direction D2.

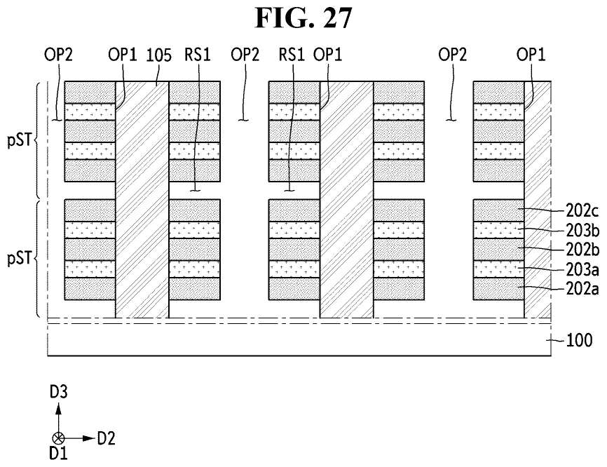

Referring to FIGS. 26 and 27, the first material layer 201 exposed by the second opening OP2 may be removed so that a first recess region RS1 may be formed between the (2-3)th material layer 202c and the (2-1)th material layer 202a, which are adjacent to each other in the third direction D3.

The first material layer 201 may be isotropically etched by an etching process having etch selectivity with respect to the (2-1)th to (2-3)th material layers 202a, 202b and 202c, the (3-1)th and (3-2)th material layers 203a and 203b, and the supporter 105. When the first material layer 201 is removed, the (2-1)th to (2-3)th material layers 202a, 202b and 202c and the (3-1)th and (3-2)th material layers 203a and 203b may be supported by the supporter 105.

A thickness of the first recess region RS1 in the third direction D3, that is, a distance between the (2-3)th material layer 202c and the (2-1)th material layer 202a, which are adjacent to each other, may be substantially the same as a thickness of the first material layer 201.

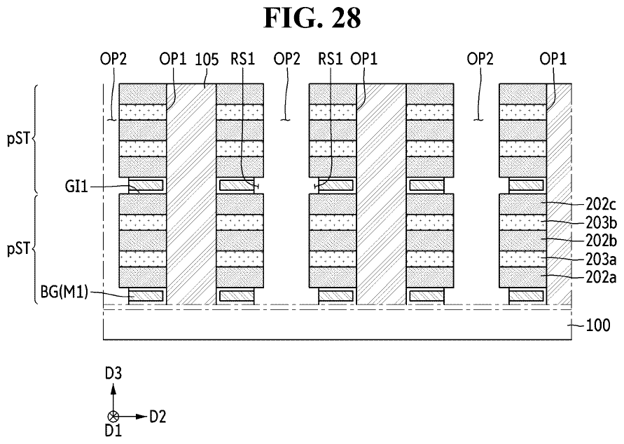

Referring to FIGS. 27 and 28, a first gate insulating layer GI1 and a back gate electrode BG disposed on the first gate insulating layer GI1, which fill a portion of the first recess region RS1, may be formed.

Since the thickness of the first recess region RS1 in the third direction D3 varies depending on the thickness of the first material layer 201 in the third direction D3, a thickness of the back gate electrode BG in the third direction D3, which is formed in the first recess region RS1, may be varied. The thickness of the first material layer 201 may be adjusted so that the thickness of the back gate electrode BG may be adjusted accordingly. The thickness of the first material layer 201 may be, for example, about 10 Å to 600 Å.

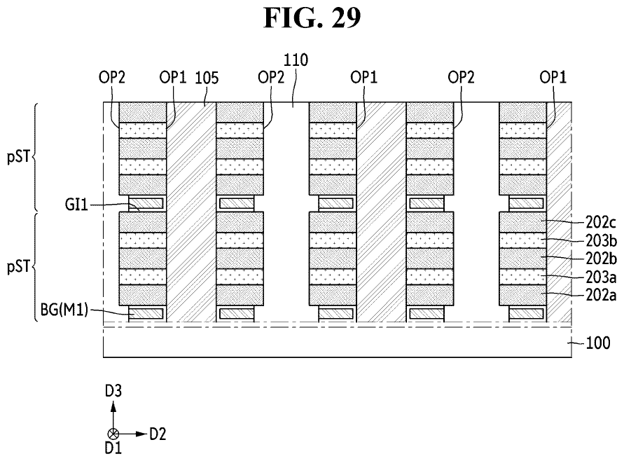

Referring to FIGS. 28 and 29, a first gap fill layer 110 for filling the first recess region RS1 and the second opening OP2 may be formed. The first gap fill layer 110 may be formed of an insulating material having etch selectivity with respect to the (2-1)th to (2-3)th material layers 202a, 202b and 202c and the (3-1)th and (3-2)th material layers 203a and 203b.

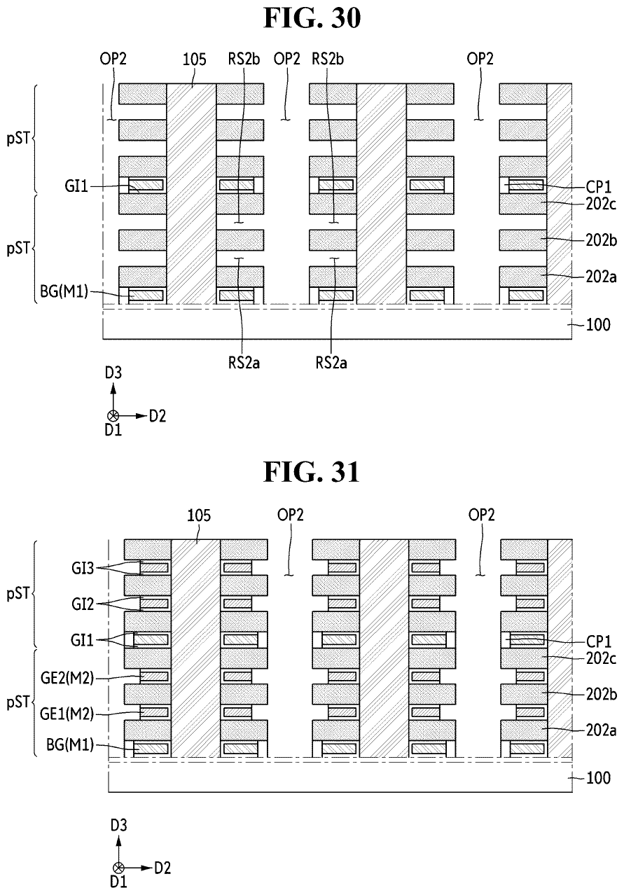

Referring to FIG. 30, at least a portion of the first gap fill layer 110 in the second opening OP2 may be removed so that a first capping pattern CP1 for filling the first recess region RS1 may be formed. The first capping pattern CP1 may be a remaining portion of the first gap fill layer 110 for filling the first recess region RS1.

Subsequently, the (3-1)th material layer 203a exposed by the second opening OP2 may be removed so that a (2-1)th recess region RS2a may be formed between the (2-1)th material layer 202a and the (2-2)th material layer 202b, and the (3-2)th material layer 203b may be removed so that a (2-2)th recess region RS2b may be formed between the (2-2)th material layer 202b and the (2-3)th material layer 202c. The (3-1)th and (3-2)th material layers 203a and 203b may be isotropically etched by an etching process having etch selectivity with respect to the (2-1)th to (2-3)th material layers 202a, 202b and 202c, the supporter 105 and the first capping pattern CP1.

Each thickness of the (2-1)th and (2-2)th recess regions RS2a and RS2b in the third direction D3 may be substantially the same as each thickness of the (3-1)th and (3-2)th material layers 203a and 203b.

Referring to FIGS. 30 and 31, the second gate insulating layer GI2 and the first gate electrode GE1, which fill a portion of the (2-1)th recess region RS2a, and the third gate insulating layer G13 and the second gate electrode GE2, which fill a portion of the (2-2)th recess region RS2b, may be formed. The first gate electrode GE1 and the second gate electrode GE2 may include a second conductive pattern M2. The second gate insulating layer GI2 may be extended along an upper surface of the first gate electrode GE1, and a side and a lower surface of the first gate electrode GE1, which are directed toward the supporter 105. The third gate insulating layer GI3 may be extended along an upper surface of the second gate electrode GE2, and a side and a lower surface of the second gate electrode GE2, which are directed toward the supporter 105.

For example, a preliminary gate dielectric layer extended along the second opening OP2 and the (2-1)th and (2-2)th recess regions RS2a and RS2b, and a preliminary gate electrode extended along the preliminary gate dielectric layer may be formed. The preliminary gate electrode may fill the (2-1)th and (2-2)th recess regions RS2a and RS2b on the preliminary gate dielectric layer. A portion of the preliminary gate electrode and the preliminary gate dielectric layer may be etched so that second and third gate insulating layers GI2 and G13 and first and second gate electrodes GE1 and GE2 may be formed to partially fill the (2-1)th and (2-2)th recess regions RS2a and RS2b. Etching a portion of the preliminary gate dielectric layer and the preliminary gate electrode may be performed by etch-back technique.

The thickness of the (3-1)th material layer 203a may be adjusted so that the thickness of the first gate electrode GE1 formed in the (2-1)th recess region RS2a may be adjusted. The thickness of the (3-2)th-th material layer 203b may be adjusted so that the thickness of the second gate electrode GE2 formed in the (2-2)th recess region RS2b may be adjusted. The thickness of each of the (3-1)th and (3-2)th material layers 203a and 203b may be, for example, about 10 Å to 600 Å.

Referring to FIGS. 31 and 23, the supporter 105 may be removed so that the first opening (OP1 of FIG. 25) may be formed again. The first to third gate insulating layers GI1, GI2, and GI3 may be exposed by the first opening OP1.

A portion of the first gate insulating layer GI1 and the back gate electrode BG, a portion of the second gate insulating layer GI2 and the first gate electrode GE1, and a portion of the third gate insulating layer GI3 and the second gate electrode GE2 may be removed through the first opening OP1. A first spacer pattern SS1 may be formed in a space from which a portion of the first gate insulating layer GI1 and the back gate electrode BG is removed, a second spacer pattern SS2 may be formed in a space from which a portion of the second gate insulating layer GI2 and the first gate electrode GE1 is removed, and a third spacer pattern SS3 may be formed in a space from which a portion of the third gate insulating layer GI3 and the second gate electrode GE2 is removed.

A second capping pattern CP2 for filling the (2-1)th recess region RS2a may be formed on the second gate insulating layer GI2 and the first gate electrode GE1. A third capping pattern CP3 for filling the (2-2)th recess region RS2b may be formed on the third gate insulating layer GI3 and the second gate electrode GE2.

Subsequently, a portion of the (2-1)th to (2-3)th material layers 202a, 202b and 202c may be removed through the first opening OP1 so that first to third semiconductor patterns SP1, SP2 and SP3 may be formed. A gap may be respectively formed between the first spacer pattern SS1 and the second spacer pattern SS2, between the second spacer pattern SS2 and the third spacer pattern SS3, and between the third spacer pattern SS3 and the first spacer pattern SS1.

A capacitor CAP may be formed in the first opening OP1. A storage electrode SE may be formed in each gap. A bit line BL may be formed in the second opening OP2.

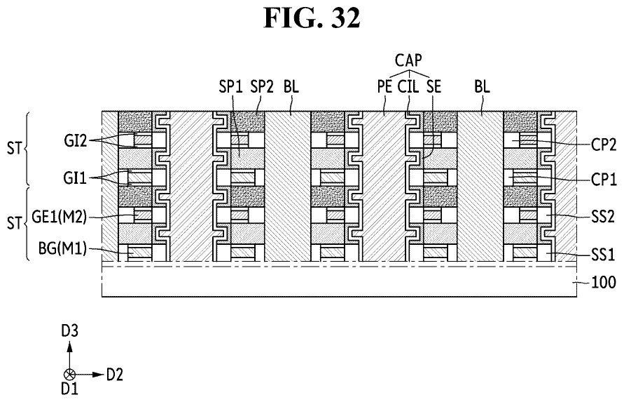

FIG. 32 is an exemplary schematic cross-sectional view illustrating a semiconductor memory device according to some embodiments. For reference, FIG. 32 is a cross-sectional view illustrating the first semiconductor pattern SP1 taken along the second direction D2. For convenience of description, a redundant portion of that described with reference to FIGS. 1 to 31 will be briefly described, and the description will be based on differences from the description of FIGS. 1 to 31.

Referring to FIG. 32, in the semiconductor memory device according to some embodiments, the structure ST may include a first semiconductor pattern SP1, a second semiconductor pattern SP2, a back gate electrode BG, a first gate electrode GE1, a first gate insulating layer GI1, a second gate insulating layer G12, a first spacer pattern SS1, a second spacer pattern SS2, a first capping pattern CP1, a second capping pattern CP2, and a capacitor CAP. In the structure ST, the back gate electrode BG, the first semiconductor pattern SP1, the first gate electrode GE1 and the second semiconductor pattern SP2 may be sequentially stacked along the third direction D3. The first semiconductor pattern SP1 and the second semiconductor pattern SP2 may be sequentially spaced apart from each other along the third direction D3.

In some embodiments, the first semiconductor pattern SP1 and the second semiconductor pattern SP2 may include their respective materials different from each other, and/or may have their respective physical properties (e.g., shape, dimensions, etc.) different from each other. The physical properties may also include, for example, a composition, a crystal direction (i.e., orientation) and an average crystal grain size. For example, the first semiconductor pattern SP1 and the second semiconductor pattern SP2 may include the same material, but may have their respective compositions different from each other.

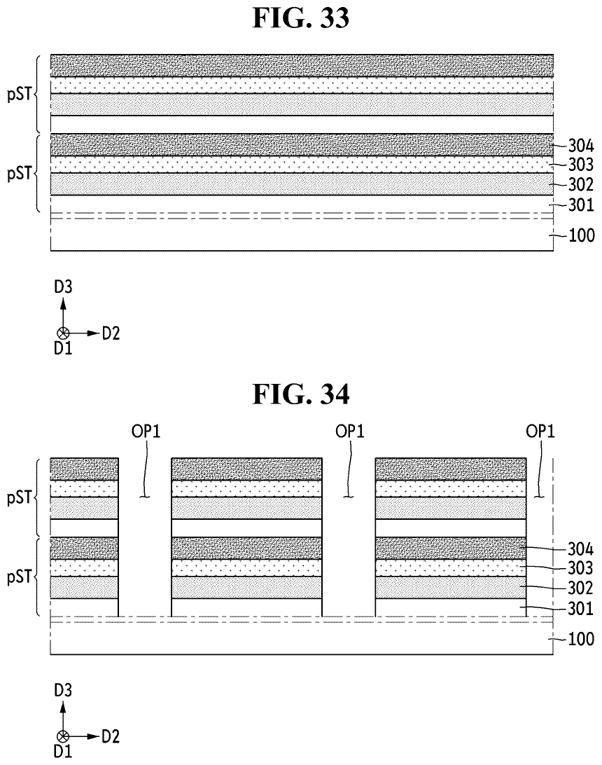

FIGS. 33 to 41 are schematic views illustrating intermediate processes in an example method for fabricating a semiconductor memory device according to some embodiments. For convenience of description, a redundant portion of that described with reference to FIGS. 1 to 32 will be briefly described, and the description will be based on differences from the description of FIGS. 1 to 32.

Referring to FIG. 33, a preliminary structure pST, which is repeatedly stacked along the third direction D3, may be formed on a substrate 100. The preliminary structure pST may include a first material layer 301, a second material layer 302, a third material layer 303, and a fourth material layer 304, which are sequentially stacked in the third direction D3.

The second material layer 302 and the fourth material layer 304 may include their respective materials different from each other and/or may have their respective physical properties different from each other. Each of the second material layer 302 and the fourth material layer 304 may include, for example, silicon, germanium, silicon-germanium or indium gallium zinc oxide (IGZO). The first material layer 301 and the third material layer 303 may be formed of a material having etch selectivity with respect to the second and fourth material layers 302 and 304. The second material layer 302 may be formed of a material having etch selectivity with respect to the fourth material layer 304.

Referring to FIG. 34, a first opening OP1 extending in the third direction D3 through a plurality of preliminary structures pST may be formed. A plurality of first openings OP1 may be arranged spaced apart from each other in the second direction D2.

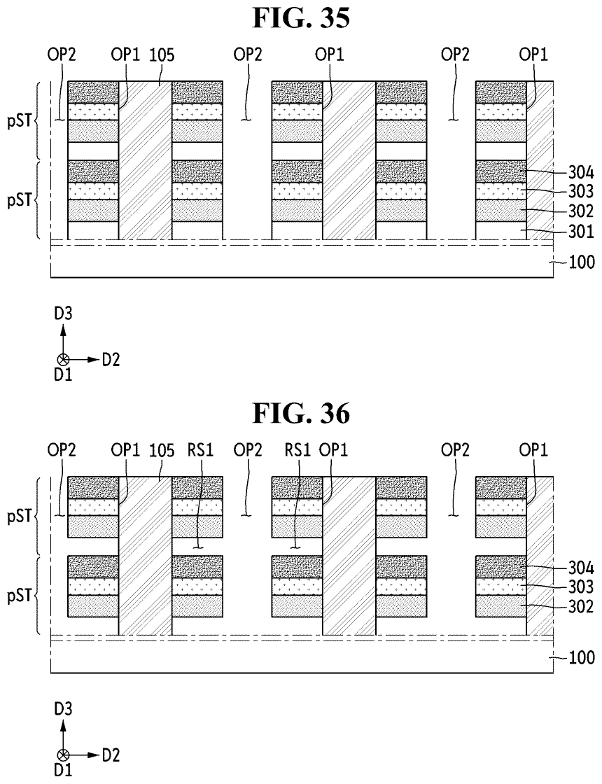

Referring to FIG. 35, a supporter 105 for filling the first opening OP1 may be formed. The supporter 105 may be formed of a material having etch selectivity with respect to the first and third material layers 301 and 303.

A second opening OP2 extending in the third direction D3 through the plurality of preliminary structures pST may be formed. The second opening OP2 may be formed between the supporters 105 adjacent to each other. A plurality of second openings OP2 may be formed, spaced apart from each other in the second direction D2.

Referring to FIGS. 35 and 36, the first material layer 301 exposed by the second opening OP2 may be removed so that a first recess region RS1 may be formed between the fourth material layer 304 and the second material layer 302, which are adjacent to each other in the third direction D3.

The first material layer 301 may be isotropically etched by an etching process having etch selectivity with respect to the second to fourth material layers 302, 303 and 304 and the supporter 105. When the first material layer 301 is removed, the second to fourth material layers 302, 303 and 304 may be supported by the supporter 105.

A thickness of the first recess region RS1 in the third direction D3, that is, a distance between the fourth material layer 304 and the second material layer 302, which are adjacent to each other, may be substantially the same as a thickness of the first material layer 301.

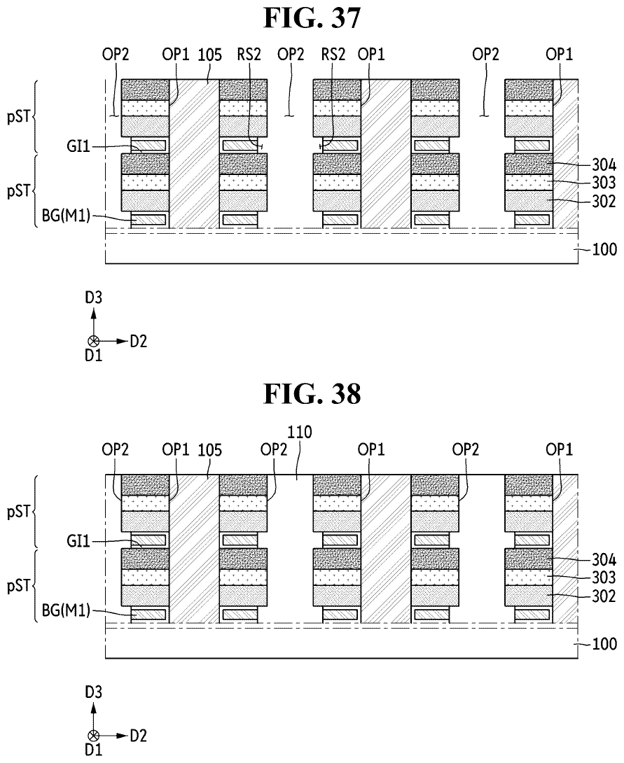

Referring to FIGS. 36 and 37, a first gate insulating layer GI1 and a back gate electrode BG, which fill a portion of the first recess region RS1, may be formed.

Since the thickness of the first recess region RS1 in the third direction D3 varies depending on the thickness of the first material layer 301 in the third direction D3, a thickness of the back gate electrode BG in the third direction D3, which is formed in the first recess region RS1, may be varied. The thickness of the first material layer 301 may be adjusted so that the thickness of the back gate electrode BG may be adjusted. The thickness of the first material layer 301 may be, for example, about 10 Å to 600 Å.

Referring to FIGS. 37 and 38, a first gap fill layer 110 for filling the first recess region RS1 and the second opening OP2 may be formed. The first gap fill layer 110 may be formed of an insulating material having etch selectivity with respect to the third material layer 303.

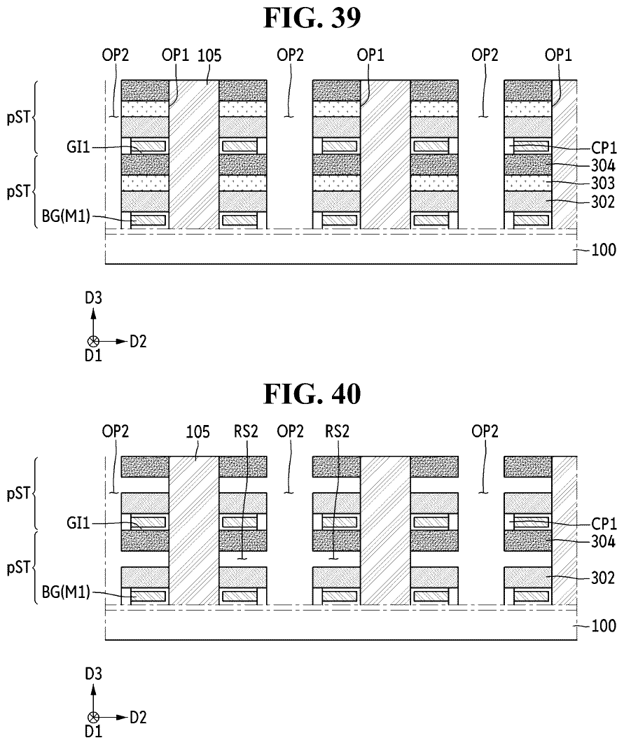

Referring to FIG. 39, at least a portion of the first gap fill layer 110 in the second opening OP2 may be removed so that a first capping pattern CP1 for filling the first recess region RS1 may be formed. The first capping pattern CP1 may be a remaining portion of the first gap fill layer 110 for filling the first recess region RS1.

Referring to FIGS. 39 and 40, the third material layer 303 may be removed through the second opening OP2 so that a second recess region RS2 may be formed between the second material layer 302 and the fourth material layer 304, which are adjacent to each other in the third direction D3. The third material layer 303 may be isotropically etched by an etching process having etch selectivity with respect to the second and fourth material layers 302 and 304, the supporter 105 and the first capping pattern CP1.

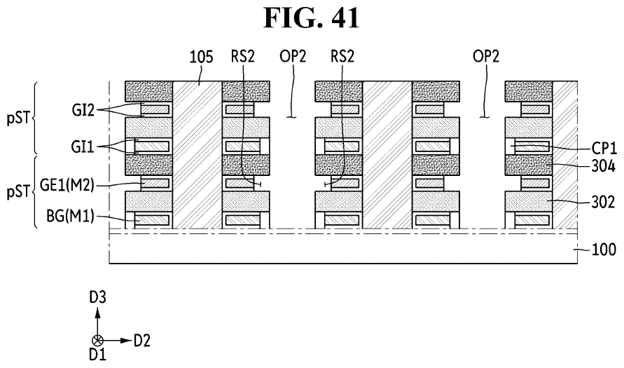

Referring to FIGS. 40 and 41, a second gate insulating layer GI2 and a first gate electrode GE1, which fill a portion of the second recess region RS2, may be formed. The first gate electrode GE1 may include a second conductive pattern M2. The second gate insulating layer GI2 may be extended along an upper surface of the first gate electrode GE1, and a side and a lower surface of the first gate electrode GE1, which are directed toward the supporter 105.

Referring to FIGS. 41 and 32, the supporter 105 may be removed so that the first opening (OP1 of FIG. 34) may be formed again. The first and second gate insulating layers GI1 and GI2 may be exposed by the first opening OP1.

A portion of the first gate insulating layer GI1 and the back gate electrode BG and a portion of the second gate insulating layer GI2 and the first gate electrode GE1 may be removed through the first opening OP1. A first spacer pattern SS1 may be formed in a space from which a portion of the first gate insulating layer GI1 and the back gate electrode BG is removed, and a second spacer pattern SS2 may be formed in a space from which a portion of the second gate insulating layer GI2 and the first gate electrode GE1 is removed.

A second capping pattern CP2 for filling the second recess region RS2 may be formed on the second gate insulating layer GI2 and the first gate electrode GE1.

Subsequently, a portion of the second and fourth material layers 302 and 304 may be removed through the first opening OP1 so that first and second semiconductor patterns SP1 and SP2 may be formed. A gap may be respectively formed between the first spacer pattern SS1 and the second spacer pattern SS2 and between the second spacer pattern SS2 and the first spacer pattern SS1.

A capacitor CAP may be formed in the first opening OP1. A storage electrode SE may be formed in each gap. A bit line BL may be formed in the second opening OP2.

Although the embodiments of the present disclosure have been described with reference to the accompanying drawings, it will be apparent to those skilled in the art that the present disclosure may be fabricated in various forms without being limited to the above-described embodiments and may be embodied in other specific forms without departing from technical spirits and essential characteristics of the present disclosure. Thus, the above embodiments are to be considered in all respects as illustrative and not restrictive.

What is claimed is:

1. A semiconductor memory device, comprising:
a back gate electrode, which includes a first conductive pattern, on a substrate;
a first gate electrode, which includes a second conductive pattern, on the back gate electrode; and
a first semiconductor pattern between the back gate electrode and the first gate electrode,
wherein the first conductive pattern and the second conductive pattern include respective materials and/or respective physical properties different from each other.

2. The semiconductor memory device of claim 1, wherein the first conductive pattern has a composition different from a composition of the second conductive pattern.

3. The semiconductor memory device of claim 1, wherein a first size of an average crystal grain of the first conductive pattern is different from a second size of an average crystal grain of the second conductive pattern.

4. The semiconductor memory device of claim 1, wherein a first crystal direction of the first conductive pattern is different from a second crystal direction of the second conductive pattern.

5. The semiconductor memory device of claim 1, wherein the back gate electrode and the first gate electrode extend in a first direction parallel with an upper surface of the substrate, and
a length of the back gate electrode in a second direction, parallel with the upper surface of the substrate and crossing the first direction, is different from a length of the first gate electrode in the second direction.

6. The semiconductor memory device of claim 1, wherein a first thickness of the back gate electrode in a third direction perpendicular to the upper surface of the substrate is different from a second thickness of the first gate electrode in the third direction.

7. The semiconductor memory device of claim 1, wherein the back gate electrode further includes a third conductive pattern comprising a material different from that of the first conductive pattern and/or having physical properties different from those of the first conductive pattern.

8. The semiconductor memory device of claim 1, wherein the first gate electrode further includes a third conductive pattern comprising a material different from that of the second conductive pattern and/or having physical properties different from those of the second conductive pattern.

9. A semiconductor memory device, comprising:
a plurality of structures stacked on a substrate in a third direction perpendicular to an upper surface of the substrate; and
a bit line extending in the third direction,
wherein each of the plurality of structures includes:
a back gate electrode including a first conductive pattern;
a first semiconductor pattern on the back gate electrode;
a first gate electrode, which includes a second conductive pattern, on the first semiconductor pattern; and
a data storage element on the first semiconductor pattern,
wherein the bit line is electrically connected to a first end of the first semiconductor pattern,
wherein the data storage element is electrically connected to a second end of the first semiconductor pattern, and
wherein the first conductive pattern and the second conductive pattern include respective materials and/or respective physical properties that are different from each other.

10. The semiconductor memory device of claim 9, wherein each of the plurality of structures further includes a second semiconductor pattern, a second gate electrode on the first gate electrode, and an interlayer insulating layer between the first gate electrode and the second gate electrode,
the back gate electrode is between the second semiconductor pattern and the first semiconductor pattern,
the bit line is electrically connected to a first end of the second semiconductor pattern, and
the data storage element is electrically connected to a second end of the second semiconductor pattern.

11. The semiconductor memory device of claim 10, wherein the second gate electrode includes the second conductive pattern.

12. The semiconductor memory device of claim 9, wherein each of the plurality of structures further includes a second semiconductor pattern on the first gate electrode,
the first gate electrode is between the first semiconductor pattern and the second semiconductor pattern,
the bit line is electrically connected to a first end of the second semiconductor pattern,
the data storage element is electrically connected to a second end of the second semiconductor pattern, and
the first semiconductor pattern and the second semiconductor pattern include the same material.

13. The semiconductor memory device of claim 9, wherein each of the plurality of structures further includes a second semiconductor pattern on the first gate electrode,
the first gate electrode is between the first semiconductor pattern and the second semiconductor pattern,
the bit line is electrically connected to a first end of the second semiconductor pattern,
the data storage element is electrically connected to a second end of the second semiconductor pattern, and
the first semiconductor pattern and the second semiconductor pattern include respective materials different from each other.

14. The semiconductor memory device of claim 9, wherein each of the plurality of structures further includes a second semiconductor pattern on the first gate electrode, a second gate electrode on the second semiconductor pattern, and a third semiconductor pattern on the second gate electrode,
the bit line is electrically connected to a first end of the second semiconductor pattern and a first end of the third semiconductor pattern, and
the data storage element is electrically connected to a second end of the second semiconductor pattern and a second end of the third semiconductor pattern.

15. The semiconductor memory device of claim 14, wherein the second gate electrode includes the second conductive pattern.

16. The semiconductor memory device of claim 9, wherein each of the plurality of structures further includes a first spacer pattern between the back gate electrode and the data storage element, and a second spacer pattern between the first gate electrode and the data storage element,
the data storage element includes a storage electrode, a plate electrode, and a capacitor dielectric layer between the storage electrode and the plate electrode, and
the storage electrode is between the first spacer pattern and the second spacer pattern.

17. A semiconductor memory device, comprising:
a plurality of structures stacked on a substrate in a third direction perpendicular to an upper surface of the substrate; and
a bit line extending in the third direction,
wherein each of the plurality of structures includes:
a back gate electrode extending in a first direction parallel with the upper surface of the substrate, including a first conductive pattern;
a first gate insulating layer on upper and lower surfaces of the back gate electrode, a first gate electrode, extending in the first direction and including a second conductive pattern, on the back gate electrode;
a second gate insulating layer on a lower surface of the first gate electrode;
a first semiconductor pattern, extending in a second direction parallel with the upper surface of the substrate and crossing the first direction, between the back gate electrode and the first gate electrode; and
a data storage element on the first semiconductor pattern,
wherein the bit line is electrically connected to a first end of the first semiconductor pattern,
wherein the data storage element is electrically connected to a second end of the first semiconductor pattern, and
wherein the first conductive pattern and the second conductive pattern include respective materials and/or have respective physical properties different from each other.

18. The semiconductor memory device of claim 17, wherein each of the plurality of structures further includes:
a second gate electrode on the first gate electrode;
an interlayer insulating layer between the first gate electrode and the second gate electrode;
a first spacer pattern between the back gate electrode and the data storage element;
a first capping pattern between the back gate electrode and the bit line;
a second spacer pattern between the first gate electrode, the interlayer insulating layer and the second gate electrode and the data storage element; and
a second capping pattern between the first gate electrode, the interlayer insulating layer and the second gate electrode and the bit line.

19. The semiconductor memory device of claim 17, wherein each of the plurality of structures further includes a second semiconductor pattern on the first gate electrode,
the first gate electrode is between the first semiconductor pattern and the second semiconductor pattern, and
the second gate insulating layer is on an upper surface of the first gate electrode.

20. The semiconductor memory device of claim 17, wherein each of the plurality of structures further includes:
a second semiconductor pattern on the first gate electrode;
a first spacer pattern between the back gate electrode and the data storage element;
a first capping pattern between the back gate electrode and the bit line;
a second spacer pattern between the first gate electrode and the data storage element; and
a second capping pattern between the first gate electrode and the bit line.
